(19) United States
(12) Patent Application Publication
(10) Pub. No.: US 2026/0068435 A1
(43) Pub. Date: Mar. 5, 2026

(54) ARRAY SUBSTRATE AND DISPLAY PANEL

(71) Applicant: Wuhan Tianma Microelectronics Co., Ltd. Shanghai Branch, Shanghai (CN)

(72) Inventor: Xi CHEN, Shanghai (CN)

(73) Assignee: Wuhan Tianma Microelectronics Co., Ltd. Shanghai Branch, Shanghai (CN)

(21) Appl. No.: 19/381,349

(22) Filed: Nov. 6, 2025

(30) Foreign Application Priority Data
Aug. 8, 2025 (CN) 202511114596.2

(51) Int. Cl. H10K 59/121; H10D 86/01; H10D 86/40; H10D 86/60; H10H 29/01; H10H 29/32; H10H 29/41; H10K 59/12; H10K 59/124

(52) U.S. Cl. CPC H10K 59/1213; H10D 86/0221; H10D 86/421; H10D 86/481; H10D 86/60; H10H 29/012; H10H 29/32; H10H 29/41; H10K 59/1201; H10K 59/1216; H10K 59/124

(57) ABSTRACT

Provided are an array substrate and a display panel. The array substrate includes a substrate and a circuit function layer located on one side of the substrate. The circuit function layer includes multiple transistors, and the multiple transistors include a drive transistor. A channel region of the drive transistor includes at least two active layers. Along a first direction, the at least two active layers are stacked and sequentially connected. The first direction is a direction from the substrate toward the circuit function layer. The channel region includes a first channel region and a second channel region connected along a second direction. Along a third direction, the length of the first channel region is less than the length of the second channel region. The second direction and the third direction intersect and are both parallel to a plane where the substrate is located.

### CROSS-REFERENCE TO RELATED APPLICATION

This application claims priority to Chinese Patent Application No. 202511114596.2 filed Aug. 8, 2025, the disclosure of which is incorporated herein by reference in its entirety.

### TECHNICAL FIELD

The present disclosure relates to the field of display technology, and in particular, to an array substrate and a display panel.

### BACKGROUND

In LED display panels, a pixel circuit is commonly used to drive an LED to emit light. The area occupied by the pixel circuit is much larger than the area occupied by the LED. By the reduction of the area of the pixel circuit, space utilization can be further improved, and effects such as increasing display resolution can be achieved.

In the related art, a pixel circuit typically includes a drive transistor and a switch transistor. The switch transistor is used to quickly switch the operating state of the circuit, and the drive transistor is used for providing a stable current to drive the LED to emit light. To ensure performance stability and reliability of the drive transistor and maintain display quality, the drive transistor is usually designed with a relatively long channel length, which results in a larger area occupied by the drive transistor in a horizontal plane. This becomes a major factor affecting the area of the pixel circuit, making it difficult to further reduce the area of the pixel circuit.

### SUMMARY

The present disclosure provides an array substrate and a display panel to further reduce the area occupied by a pixel circuit and improve space utilization.

In one aspect of the present disclosure, an array substrate is provided. The array substrate includes a substrate and a circuit function layer located on one side of the substrate.

The circuit function layer includes multiple transistors. The multiple transistors include a drive transistor.

A channel region of the drive transistor includes at least two active layers.

Along a first direction, the at least two active layers are stacked and sequentially connected. The first direction is a direction from the substrate toward the circuit function layer.

The channel region includes a first channel region and a second channel region connected along a second direction. Along a third direction, the length of the first channel region is less than the length of the second channel region. The second direction and the third direction intersected with each other and the second direction and the third direction are both parallel to a plane where the substrate is located.

In another aspect of the present disclosure, a display panel is provided. The display panel includes the array substrate provided by any embodiment of the present disclosure and a light-emitting layer.

The light-emitting layer is located on one side of the circuit function layer away from the substrate and includes multiple light-emitting elements coupled to the drive transistor.

In the technical solution of embodiments of the present disclosure, a channel region of the drive transistor in the pixel circuit includes at least two active layers, and the at least two active layers are stacked and sequentially connected along a direction from the substrate toward the circuit function layer. In this manner, the channel of the drive transistor can extend both in a direction parallel to the substrate and in a direction intersecting a plane where the substrate is located, forming a three-dimensional channel. Thus, the projection area of the channel region of the drive transistor on the substrate can be reduced, the area occupied by the drive transistor can be decreased, and the area of the pixel circuit can be effectively reduced. Additionally, the channel region of the drive transistor includes a first channel region and a second channel region connected along the second direction, and along the third direction, the length of the first channel region is less than the length of the second channel region. In this manner, the channel region of the drive transistor can have a notch at a connection corner between the first channel region and the second channel region, electrical connections can be achieved between different structures as needed in the notch region, such as an electrical connection between a gate of the drive transistor and other circuit structures, and increased difficulty in circuit connections due to the multi-layer active layer design of the drive transistor can be avoided.

It is to be understood that the contents described in this part are not intended to identify key or important features of embodiments of the present disclosure and are not intended to limit the scope of the present disclosure. Other features of the present disclosure are apparent from the description provided hereinafter.

### BRIEF DESCRIPTION OF DRAWINGS

To illustrate technical solutions in embodiments of the present disclosure more clearly, accompanying drawings used in the description of the embodiments are briefly described below. The accompanying drawings described below illustrate part of embodiments of the present disclosure, and those of ordinary skill in the art may acquire other accompanying drawings based on the accompanying drawings described below on the premise that no creative work is done.

FIG. 1 is a schematic diagram illustrating the layer structure of an active layer in a conventional array substrate.

FIG. 2 is a schematic diagram of a 2T1C pixel circuit.

FIG. 3 is a schematic diagram illustrating part of the layer structure of an array substrate according to an embodiment of the present disclosure.

FIG. 4 is an enlarged structural diagram of a channel region of a drive transistor in FIG. 3.

FIG. 5 is a sectional view of an array substrate taken along line BB′ in FIG. 3.

FIG. 6 is a sectional view of an array substrate taken along line CC′ in FIG. 3.

FIG. 7 is a schematic diagram illustrating the three-dimensional structure of a channel of a drive transistor in an array substrate according to an embodiment of the present disclosure.

FIG. 8 is a sectional view of another array substrate taken along line BB′ in FIG. 3.

FIG. 9 is a sectional view of another array substrate taken along line CC′ in FIG. 3.

FIG. 10 is a sectional view of another array substrate taken along line CC′ in FIG. 3.

FIG. 11 is a sectional view of another array substrate taken along line CC′ in FIG. 3.

FIG. 12 is a sectional view of another array substrate taken along line BB′ in FIG. 3.

FIG. 13 is a sectional view of another array substrate taken along line CC′ in FIG. 3.

FIG. 14 is a sectional view of another array substrate taken along line CC′ in FIG. 3.

FIG. 15 is another schematic diagram illustrating part of the layer structure of an array substrate according to an embodiment of the present disclosure.

FIG. 16 is a sectional view of an array substrate taken along line DD′ in FIG. 15.

FIG. 17 is a sectional view of an array substrate taken along line EE′ in FIG. 15.

FIG. 18 is a sectional view of another array substrate taken along line BB′ in FIG. 3.

FIG. 19 is a sectional view of another array substrate taken along line CC′ in FIG. 3.

FIG. 20 is a schematic diagram of a 7T1C pixel circuit.

FIG. 21 is a schematic diagram illustrating the layer structure of another array substrate according to an embodiment of the present disclosure.

FIG. 22 is a schematic diagram illustrating a stacked structure of layers where a first active layer, a second active layer, and a third active layer are located in FIG. 21.

FIG. 23 is a schematic diagram illustrating a stacked structure of a layer where a first active layer is located and a first metal layer in FIG. 21.

FIG. 24 is a schematic diagram illustrating a stacked structure of a layer where a first active layer is located, a layer where a second active layer is located, and a second metal layer in FIG. 21.

FIG. 25 is a schematic diagram illustrating a stacked structure of a layer where a first active layer is located, a layer where a third active layer is located, and a third metal layer in FIG. 21.

FIG. 26 is a sectional view of an array substrate taken along line JJ′ in FIG. 21.

FIG. 27 to FIG. 44 are sectional views illustrating a preparation process corresponding to an array substrate shown in FIG. 26.

FIG. 45 is a diagram illustrating the structure of a display panel according to an embodiment of the present disclosure.

FIG. 46 is another diagram illustrating the structure of a display panel according to an embodiment of the present disclosure.

### DETAILED DESCRIPTION

The solutions in the embodiments of the present disclosure are described clearly and completely in conjunction with drawings in the embodiments of the present disclosure from which the solutions are better understood by those skilled in the art. Apparently, the embodiments described below are part, not all, of the embodiments of the present disclosure. Based on the embodiments described herein, all other embodiments acquired by those of ordinary skill in the art on the premise that no creative work is done are within the scope of the present disclosure.

It is apparent to those skilled in the art that various modifications and changes in the present disclosure may be made without departing from the spirit or scope of the present disclosure. Accordingly, the present disclosure is intended to cover modifications and variations of the present disclosure that fall within the scope of the appended claims (the claimed technical solutions) and their equivalents. It is to be noted that the embodiments of the present disclosure, if not in collision, may be combined with one another.

First, it should be noted that unless otherwise defined, the technical terms or scientific terms used herein should have a general meaning understood by those with general skills in the field to which the present disclosure belongs. The terms such as “first” and “second” used in the present disclosure are used to distinguish different components but not used to describe any order, quantity, or significance. The term “including” and similar terms mean that the elements or objects in front of the term cover elements or objects and their equivalents listed in the back of the term, but do not exclude other elements or objects. Terms such as “connect” and “connected to” are not limited to physical or mechanical connections, but may include electrical connections, whether direct or indirect. Terms such as “upper”, “lower”, “left”, and “right” are used only to indicate a relative positional relationship, and when the absolute position of the described object is changed, the relative positional relationship may also change accordingly. Additionally, the shapes and sizes of components in the drawings do not reflect true proportions and are intended only to illustrate the content of the present disclosure.

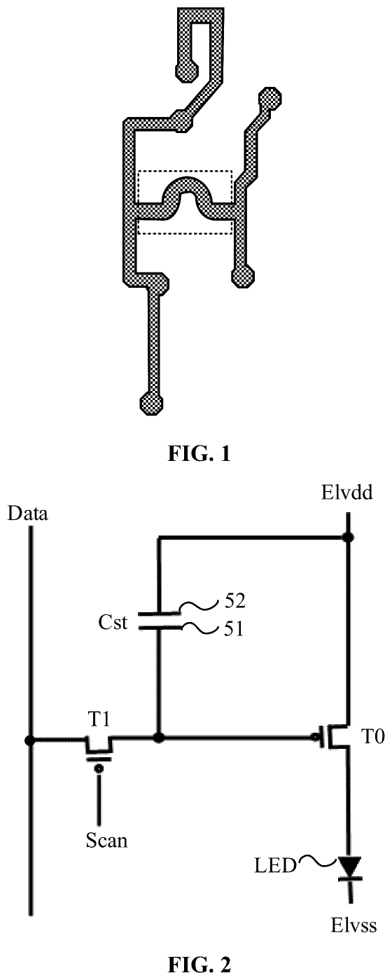

Exemplarily, FIG. 1 is a schematic diagram illustrating the layer structure of an active layer in a conventional array substrate. As shown in FIG. 1, in the related art, channels of all transistors in a pixel circuit are formed in the same active layer, and a dashed box in FIG. 1 indicates a channel region of a drive transistor. As can be seen from FIG. 1, in the related art, the channel length of the drive transistor is relatively long, resulting in a larger area occupied by the drive transistor. Due to this limitation, it is difficult to further reduce the area of the pixel circuit.

To address the preceding issue, embodiments of the present disclosure provide an array substrate and a display panel. The array substrate includes a substrate and a circuit function layer located on one side of the substrate. The circuit function layer includes multiple transistors, and the multiple transistors include a drive transistor. A channel region of the drive transistor includes at least two active layers. Along a first direction, the at least two active layers are stacked and sequentially connected. The first direction is a direction from the substrate toward the circuit function layer. The channel region includes a first channel region and a second channel region connected along a second direction. Along a third direction, the length of the first channel region is less than the length of the second channel region. The second direction and the third direction intersect and are both parallel to a plane where the substrate is located.

With the preceding technical solution adopted, the channel of the drive transistor can extend both in a direction parallel to the substrate and in a direction intersecting the plane where the substrate is located, forming a three-dimensional channel. Thus, the projection area of the channel region of the drive transistor on the substrate can be reduced, the area occupied by the drive transistor can be decreased, and the area of the pixel circuit can be effectively reduced. Additionally, the channel region of the drive transistor includes a first channel region and a second channel region connected along the second direction, and along the third direction, the length of the first channel region is less than the length of the second channel region. In this manner, a notch can be formed at a connection corner between the first channel region and the second channel region, electrical connections can be achieved between different structures as needed in the notch region, such as an electrical connection between a gate of the drive transistor and other circuit structures, and increased difficulty in circuit connections due to the multi-layer active layer design of the drive transistor can be avoided.

Currently, most pixel circuits are formed by connecting multiple transistors (T) and a storage capacitor (C). Common circuit types include, but are not limited to, 2T1C pixel circuits and 7T1C pixel circuits. The design of the drive transistor in the embodiments of the present disclosure is described in detail below, based on a 2T1C pixel circuit and with reference to the drawings.

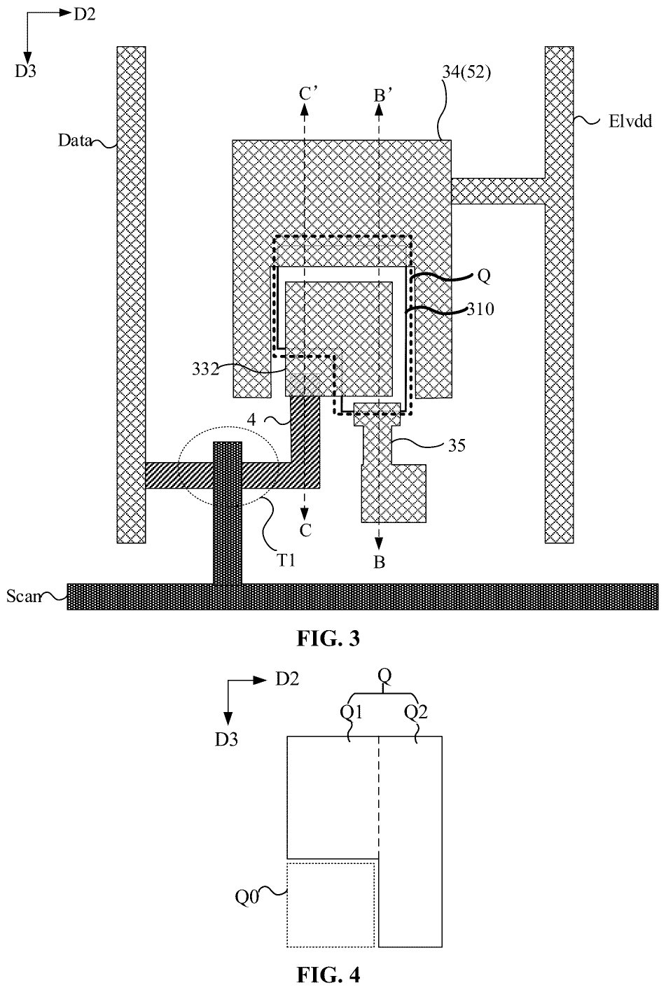

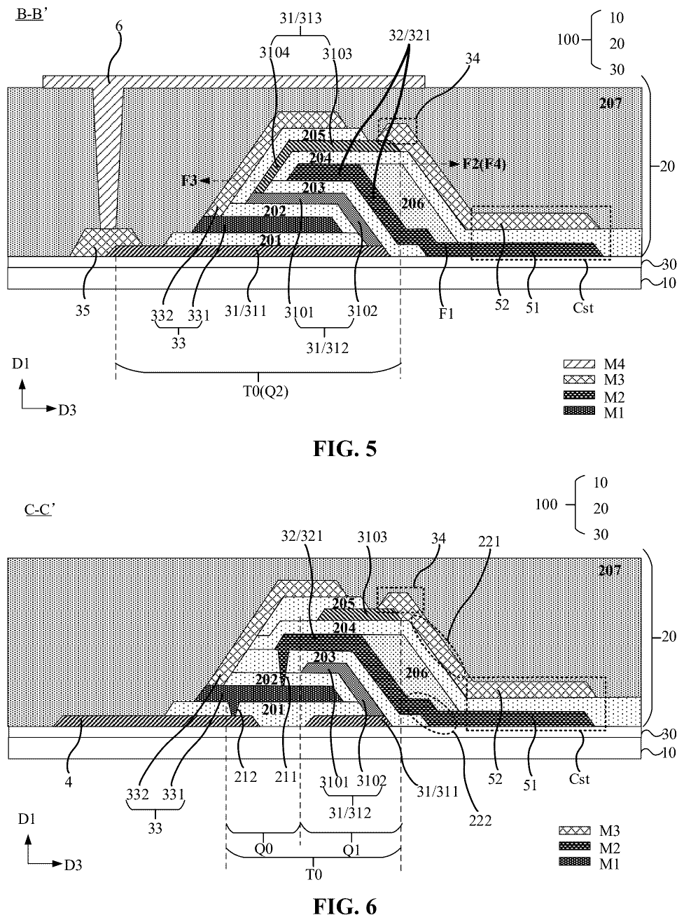

FIG. 2 is a schematic diagram of a 2T1C pixel circuit. FIG. 3 is a schematic diagram illustrating part of the layer structure of an array substrate according to an embodiment of the present disclosure, specifically showing a layout structure corresponding to the pixel circuit shown in FIG. 2. FIG. 4 is an enlarged structural diagram of a channel region of a drive transistor in FIG. 3. FIG. 5 is a sectional view of an array substrate taken along line BB′ in FIG. 3. As shown in FIG. 2 to FIG. 5, an array substrate 100 provided by an embodiment of the present disclosure includes a substrate 10 and a circuit function layer 20 located on one side of the substrate 10. The circuit function layer 20 includes multiple transistors, and the multiple transistors include a drive transistor TO. A channel region Q of the drive transistor TO includes at least two active layers 31. Along a first direction D1, the at least two active layers 31 are stacked and sequentially connected. The first direction D1 is a direction from the substrate 10 toward the circuit function layer 20. The channel region Q includes a first channel region Q1 and a second channel region Q2 connected along a second direction D2. Along a third direction D3, the length of the first channel region Q1 is less than the length of the second channel region Q2. The second direction D2 and the third direction D3 intersected with each other, and the second direction D2 and the third direction D3 are both parallel to a plane where the substrate 10 is located.

It should be noted that in FIG. 5, different filling patterns are used to distinguish active layers 31 located in different layers. In this embodiment, each active layer 31 is made of the same material. The material includes but not limited to monocrystalline silicon, polycrystalline silicon, and metal oxide, and may be specifically determined based on the required type of drive transistor.

With reference to FIG. 5, in this embodiment, the channel region Q of the drive transistor TO includes at least two stacked active layers 31. Each active layer 31 is not formed in a single process but is prepared in multiple steps (exemplarily described later), and ultimately, the active layers 31 are sequentially connected from bottom to top along the first direction D1, forming a three-dimensional channel. In this manner, a portion of the channel of the drive transistor can extend in a direction intersecting the plane where the substrate is located, thereby reducing the length of the channel that needs to extend in a direction parallel to the plane where the substrate is located. Thus, the projection area of the channel region of the drive transistor on the substrate and the area occupied by the drive transistor are reduced, thereby reducing the area of the pixel circuit.

Exemplarily, FIG. 5 illustrates a case where three active layers 31 are sequentially connected from bottom to top, forming an “S”-shaped channel. An extreme case where the tilt angles of two side surfaces of the “S”-shape are 90° is assumed. In a case where the total channel length is equal, with the technical solution of this embodiment of the present disclosure adopted, the projection area of the channel region of the drive transistor on the substrate can be reduced to approximately one-third of that of a conventional channel design (as shown in FIG. 1). This arrangement can significantly reduce the area occupied by the drive transistor, thereby reducing the area of the pixel circuit.

It should be noted that in other embodiments, the channel region of the drive transistor may include two active layers or four or more active layers, which is not limited by the embodiments of the present disclosure. If the number of active layers is excessively small, the effect of reducing the area of the pixel circuit is limited, whereas if the number of active layers is too large, design complexity and manufacturing costs will increase. In this embodiment, a design where the channel region of the drive transistor includes three active layers is adopted, which can effectively reduce the area of the pixel circuit while avoiding excessive increases in design complexity and manufacturing costs.

Further, with reference to FIG. 4, in this embodiment, the channel region Q includes a first channel region Q1 and a second channel region Q2 connected along the second direction D2, and along the third direction D3, the length of the first channel region Q1 is less than the length of the second channel region Q2.

In FIG. 4, a dashed line indicates a boundary between the first channel region Q1 and the second channel region Q2. Based on the difference in length of the channel region Q in the third direction D3 at different positions, the channel region Q is divided into the first channel region Q1 and the second channel region Q2, where the length of the first channel region Q1 in the third direction D3 is less than the length of the second channel region Q2 in the third direction D3. This configuration enables the channel region Q to have a notch at a connection corner between the first channel region Q1 and the second channel region Q2, facilitating subsequent electrical connections between a gate of the drive transistor and other circuit structures through the region where the notch is located (that is, the notch region Q0 described below), and also allowing electrical connections between other structures as needed, thereby avoiding increased difficulty in circuit connections due to the multi-layer active layer design of the drive transistor. A detailed description will be given hereinafter.

The channel region Q of the drive transistor TO can be understood as a projection region of the channel of the drive transistor TO on the substrate. Specifically, in this embodiment, the channel of the drive transistor is distributed across at least two active layers, and the label “310” in FIG. 3 indicates a composite region (or a union region) formed by a projection region of all active layers of the drive transistor on the substrate. This composite region is the region where the channel of the drive transistor is located, referred to as the channel region.

Based on the projection shape of the channel region Q, it can be understood that for any one active layer 31 of the drive transistor, the projection shape thereof is consistent with the projection shape of the channel region Q and may be divided into two regions connected along a second direction D2. The length of a region corresponding to the first channel region Q1 in the third direction D3 is less than the length of a region corresponding to the second channel region Q2 in the third direction D3. Moreover, each active layer 31 has a notch, and notches of the active layers overlap in projection along the first direction D1.

In summary, in the technical solution of embodiments of the present disclosure, a channel region of the drive transistor in the pixel circuit includes at least two active layers, and the at least two active layers are stacked and sequentially connected along a direction from the substrate toward the circuit function layer. In this manner, the channel of the drive transistor can extend both in a direction parallel to the substrate and in a direction intersecting a plane where the substrate is located, forming a three-dimensional channel. Thus, the projection area of the channel region of the drive transistor on the substrate can be reduced, the area occupied by the drive transistor can be decreased, and the area of the pixel circuit can be effectively reduced. Additionally, the channel region of the drive transistor includes a first channel region and a second channel region connected along the second direction, and along the third direction, the length of the first channel region is less than the length of the second channel region. In this manner, the channel region of the drive transistor can have a notch at a connection corner between the first channel region and the second channel region, electrical connections can be achieved between different structures as needed in the notch region, such as an electrical connection between a gate of the drive transistor and other circuit structures, and increased difficulty in circuit connections due to the multi-layer active layer design of the drive transistor can be avoided.

The design of the drive transistor is further described below in detail with an example where the channel region Q of the drive transistor TO includes three active layers 31.

FIG. 6 is a sectional view of an array substrate taken along line CC′ in FIG. 3. FIG. 7 is a schematic diagram illustrating the three-dimensional structure of a channel of a drive transistor in an array substrate according to an embodiment of the present disclosure. As shown in FIG. 5 to FIG. 7, optionally, the at least two active layers 31 include a first active layer 311, a second active layer 312, and a third active layer 313. The second active layer 312 is located on one side of the first active layer 311 away from the substrate 10. The second active layer 312 includes a first active portion 3101 and a second active portion 3102, and the second active portion 3102 is connected between the first active portion 3101 and the first active layer 311. The third active layer 313 is located on one side of the second active layer 312 away from the substrate 10. The third active layer 313 includes a third active portion 3103 and a fourth active portion 3104, and the fourth active portion 3104 is connected between the first active portion 3101 and the third active portion 3103. A plane where the second active portion 3102 is located intersects a plane where the fourth active portion 3104 is located. Along the first direction D1 and the third direction D3, the second active portion 3102 and the fourth active portion 3104 are both located on opposite sides of the first active portion 3101. A part of the orthographic projection of the second active portion 3102 on the substrate 10 is located within the first channel region Q1, and another portion of the orthographic projection of the second active portion 3102 on the substrate 10 is located within the second channel region Q2. The orthographic projection of the fourth active portion 3104 on the substrate 10 is located within the second channel region Q2. A plane where the first active layer 311 is located, a plane where the first active portion 3101 is located, and a plane where the third active portion 3103 is located are parallel to the plane where the substrate 10 is located, and the first active layer 311, the first active portion 3101, and the third active portion 3103 overlap along the first direction D1.

The overlap of the first active layer 311, the first active portion 3101, and the third active portion 3103 along the first direction D1 means that along the first direction D1, the first active layer 311, the first active portion 3101, and the third active portion 3103 have a common overlapping region. With reference to FIG. 5 and FIG. 6, along the first direction D1, a part of the first active layer 311 overlapping with the first active portion 3101 and a part of the third active portion 3103 overlapping with the first active portion 3101 are mutually overlapping, and the first active layer 311, the first active portion 3101 and the third active portion 3103 have a common overlapping region.

The plane where the second active portion 3102 is located intersects the plane where the substrate 10 is located, the plane where the fourth active portion 3104 is located intersects the plane where the substrate is located, and the planes where the second active portion 3102 and the fourth active portion 3104 are located intersect. In specific implementation, with reference to FIG. 5, optionally, an acute angle is formed between the second active portion 3102 and the first active layer 311, an obtuse angle is formed between the second active portion 3102 and the first active portion 3101, an acute angle is formed between the fourth active portion 3104 and the first active portion 3101, and an obtuse angle is formed between the fourth active portion 3104 and the third active portion 3103. In this manner, manufacturing difficulty can be reduced.

With reference to FIG. 5 to FIG. 7, planes where the first active layer 311, the first active portion 3101, and the third active portion 3103 are located are all parallel to the plane where the substrate 10 is located. From bottom to top, the first active layer 311 and the first active portion 3101 are connected through the second active portion 3102, and the first active portion 3101 and the second active portion 3102 belong to the second active layer 312; the first active portion 3101 and the third active portion 3103 are connected through the fourth active portion 3104, and the third active portion 3103 and the fourth active portion 3104 belong to the third active layer 313. Along the first direction D1, the fourth active portion 3104 and the second active portion 3102 are disposed at upper and lower sides of the first active portion 3101, and along the third direction D3, the fourth active portion 3104 and the second active portion 3102 are disposed at left and right sides of the first active portion 3101. In this manner, a sequential connection of the first active layer 311, the second active layer 312, and the third active layer 313 can be achieved, allowing the drive transistor to have a three-dimensional channel, thereby reducing the area occupied by the drive transistor.

Additionally, with reference to FIG. 5 to FIG. 7, in this embodiment, the fourth active portion 3104, which is used to connect the first active portion 3101 and the third active portion 3103, is close to the notch region Q0. In this embodiment, the orthographic projection of the fourth active portion 3104 on the substrate 10 is located only in the second channel region Q2 so that manufacturing difficulty can be reduced, and it can be ensured that the notch region Q0 is free of arrangement of active layers, thereby facilitating electrical connections between circuit structures. As for the second active portion 3102 between the first active portion 3101 and the first active layer 311, since the second active portion 3102 is located away from the notch region Q0, a part of the second active portion 3102 may be located in the first channel region Q1, and another part may be located in the second channel region Q2.

In other embodiments, if the second active portion 3102 is close to the notch region Q0 and the fourth active portion 3104 is away from the notch region, the orthographic projection of the second active portion 3102 on the substrate may be set to be located within the second channel region Q2, and the orthographic projection of the fourth active portion 3104 on the substrate may have a part located within the first channel region Q1 and another part in the second channel region Q2.

As shown in FIG. 5 and FIG. 6, optionally, in the array substrate 100, the circuit function layer 20 also includes a first insulating layer 201, a second insulating layer 202, a third insulating layer 203, a fourth insulating layer 204, and a fifth insulating layer 205. The first insulating layer 201 is partially located on one side of the first active layer 311 away from the substrate 10. The second insulating layer 202 is partially located between the second active layer 312 and the first insulating layer 201 and is connected to the first insulating layer 201 within the channel region Q. The third insulating layer 203 is partially located on one side of the second active layer 312 away from the second insulating layer 202. The fourth insulating layer 204 is partially located between the third active layer 313 and the third insulating layer 203 and is connected to the third insulating layer 203 within the channel region Q. The fifth insulating layer 205 is partially located on one side of the third active layer 313 away from the fourth insulating layer 204 and is connected to the second insulating layer 202 within the channel region Q.

Specifically, with reference to FIG. 5, in this embodiment, the first active layer 311, the second active layer 312, and the third active layer 313 are sequentially connected to form an “S”-shaped channel layer. In other words, the channel layer can be understood as an entirety formed by connecting all active layers of the drive transistor TO. The “S”-shaped channel layer has an inner surface and an outer surface. An example where the left contour of the “S” corresponds to the outer surface of the channel layer and the right contour of the “S” corresponds to the inner surface of the channel layer is used. The first insulating layer 201, the second insulating layer 202, and the fifth insulating layer 205 are sequentially connected and cover at least a portion of the outer surface of the channel layer. The third insulating layer 203 and the fourth insulating layer 204 are sequentially connected and cover the inner surface of the channel layer. Thus, the insulating layers can be used to protect the inner and outer surfaces of the channel layer and also serve as gate insulating layers.

It should be noted that the preceding first insulating layer 201 is partially located on one side of the first active layer 311 away from the substrate 10, which can be specifically understood as that a portion of the first insulating layer 201 is located on the side of the first active layer 311 away from the substrate 10, while another portion of the first insulating layer 201 is located in other regions, such as regions outside the region where the drive transistor is located. The arrangement of other insulating layers follows a similar principle and will not be repeated here.

With reference to FIG. 5 and FIG. 6, optionally, the drive transistor TO also includes at least one of a first gate 32 or a second gate 33. The second gate 33 includes a first gate portion 331 and a second gate portion 332. The first gate portion 331 is located between the first insulating layer 201 and the second insulating layer 202, and the first insulating layer 201 and the second insulating layer 202 are located between the first active layer 311 and the first active portion 3101. At least a part of the second gate portion 332 is located on one side of the fifth insulating layer 205 away from the third active portion 3103. The first gate portion 331 is electrically connected to the second gate portion 332. The first gate 32 includes a third gate portion 321. At least a part of the third gate portion 321 is located between the third insulating layer 203 and the fourth insulating layer 204 that are between the first active portion 3101 and the third active portion 3103.

With reference to FIG. 5, the first gate 32 specifically refers to a gate located on one side of the inner surface of the channel layer, and at least a portion of the first gate 32 is insulated from the channel layer by the third insulating layer 203 and the fourth insulating layer 204.

With reference to FIG. 5, the second gate 33 specifically refers to a gate located on one side of the outer surface of the channel layer, and the second gate 33 is insulated from the channel layer by the first insulating layer 201, the second insulating layer 202, and the fifth insulating layer 205.

The preceding drive transistor TO includes at least one of the first gate 32 or the second gate 33. Specifically, any of the following three configurations may be employed: In a first configuration, the drive transistor TO includes only the first gate 32. In a second configuration, the drive transistor TO includes only the second gate 33. In a third configuration, the drive transistor TO includes both the first gate 32 and the second gate 33. For the first two configurations, the drive transistor has a gate disposed only on one side of the channel layer, making it a single-gate transistor. For the third configuration, gates are disposed on opposite sides of the channel layer, making the drive transistor a dual-gate transistor. In this manner, the performance of the drive transistor can be further improved. The case where the drive transistor TO includes both the first gate 32 and the second gate 33 is used as an example for description.

For the third gate portion 321 in the first gate 32, at least a portion of the third gate portion 321 is located between the third insulating layer 203 and the fourth insulating layer 204 that are between the first active portion 3101 and the third active portion 3103. Specifically, planes where the first active portion 3101 and the third active portion 3103 are located are both parallel to the plane where the substrate is located, and at least a portion of the first gate 32 is located between the third insulating layer 203 and the fourth insulating layer 204 that are between the first active portion 3101 and the third active portion 3103. In other words, the third gate portion 321 has at least a part parallel to the plane where the substrate is located, and this portion is located between the third insulating layer 203 and the fourth insulating layer 204. Specifically, the entire third gate portion 321 may be parallel to the plane where the substrate is located and be located between the third insulating layer 203 and the fourth insulating layer 204, or a part of the third gate portion 321 may be parallel to the plane where the substrate 10 is located and be located between the third insulating layer 203 and the fourth insulating layer 204, and another portion of the third gate portion 321 may be located in a plane intersecting the plane where the substrate 10 is located.

With reference to FIG. 5 and FIG. 6, as a feasible implementation, optionally, the third gate portion 321 extends from a region between the first active portion 3101 and the third active portion 3103 to one side of the third insulating layer 203 away from the second active portion 3102. In this case, a part of the third gate portion 321 is parallel to the plane where the substrate is located, and another portion intersects the plane where the substrate is located. With this configuration, it is ensured that the third gate portion 321 has a relatively large projection area on the channel layer, thereby ensuring the control capability of the first gate 32 over the drive transistor.

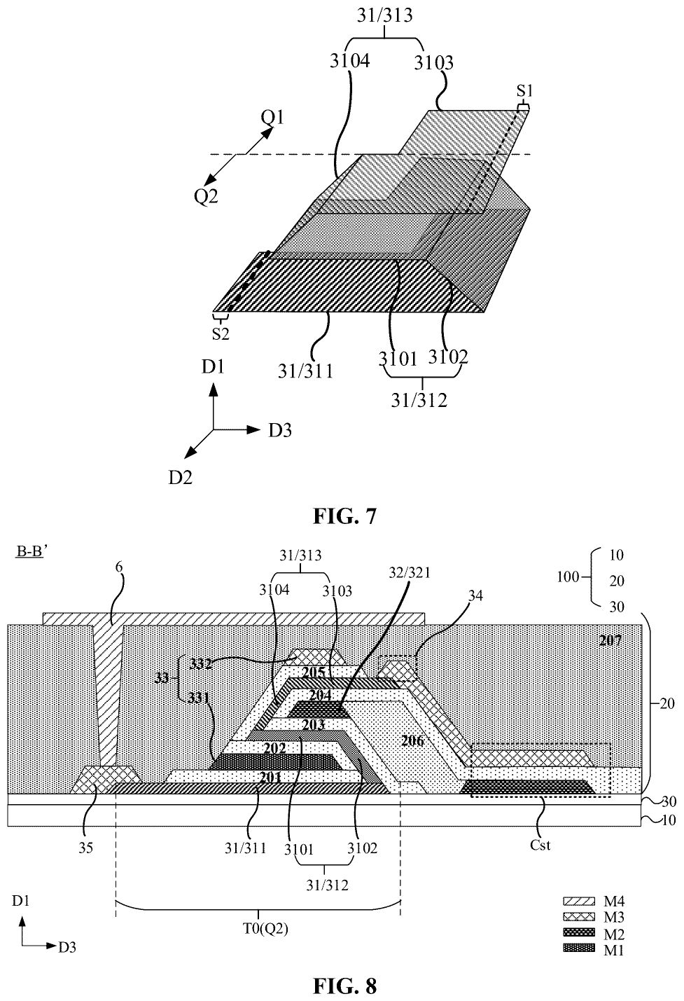

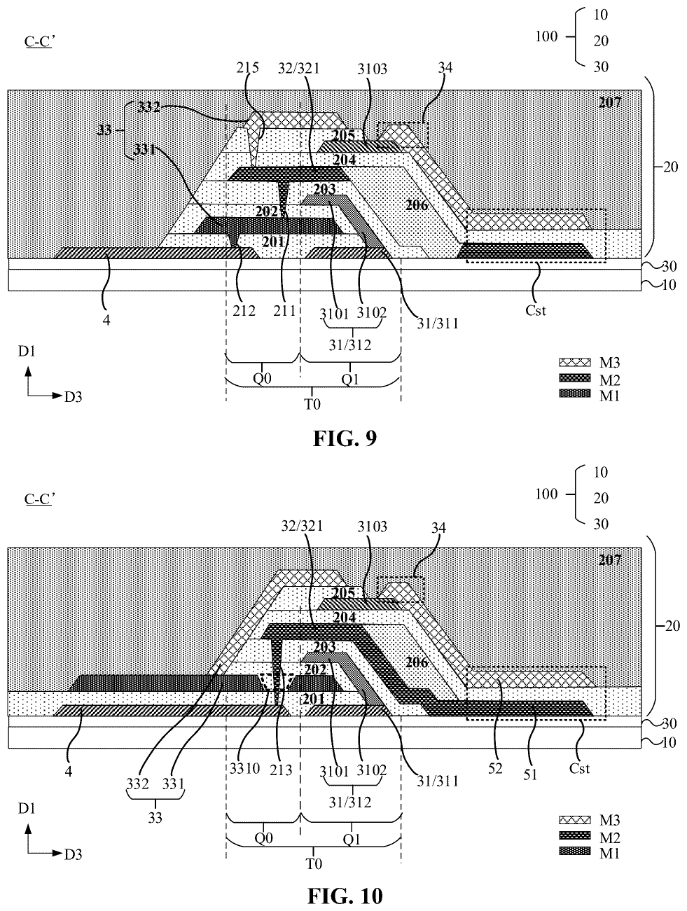

FIG. 8 is a sectional view of another array substrate taken along line BB′ in FIG. 3. FIG. 9 is a sectional view of another array substrate taken along line CC′ in FIG. 3. As shown in FIG. 8 and FIG. 9, as another feasible implementation, optionally, the third gate portion 321 is parallel to the plane where the substrate 10 is located and is located between the third insulating layer 203 and the fourth insulating layer 204 that are between the first active portion 3101 and the third active portion 3103.

Similarly, the third active portion 3103 is parallel to the plane where the substrate is located, and therefore, for the second gate portion 332, at least a part of the second gate portion 332 is located on one side of the fifth insulating layer 205 away from the third active portion 3103. In other words, the second gate portion 332 has at least a part parallel to the plane where the substrate is located, and this portion is located on the side of the fifth insulating layer 205 away from the third active portion 3103. Specifically, the entire second gate portion 332 may be parallel to the plane where the substrate is located and be located on the side of the fifth insulating layer 205 away from the third active portion 3103, or a part of the second gate portion 332 may be parallel to the plane where the substrate 10 is located and be located on the side of the fifth insulating layer 205 away from the third active portion 3103, and another portion of the second gate portion 332 may be located in a plane intersecting the plane where the substrate 10 is located.

With reference to FIG. 5 and FIG. 6, as a feasible implementation, optionally, the second gate portion 332 extends from one side of the fifth insulating layer 205 away from the third active portion 3103 to one side of the fifth insulating layer 205 away from the fourth active portion 3104 and is connected to the first gate portion 331. In this case, a part of the second gate portion 332 is parallel to the plane where the substrate is located, and another portion intersects the plane where the substrate is located. With this configuration, it can be ensured that the second gate portion 332 has a relatively large projection area on the channel layer, thereby ensuring the control capability of the second gate 33 over the drive transistor. Moreover, an electrical connection between the second gate portion 332 and the first gate portion 331 is facilitated, allowing direct contact and electrical connection between the second gate portion 332 and the first gate portion 331 and thus reducing complexity of the manufacturing process.

With reference to FIG. 8 and FIG. 9, as another feasible implementation, optionally, the plane where the second gate portion 332 is located is parallel to the plane where the substrate 10 is located, and the second gate portion 332 is located on the side of the fifth insulating layer 205 away from the third active portion 3103. In this case, the first gate portion 331 and the second gate portion 332 may be set to overlap with the notch region Q0, allowing the second gate portion 332 and the first gate portion 331 to be electrically connected in the notch region Q0 through a via.

With reference to FIG. 4 and FIG. 6, optionally, a region where the drive transistor TO is located includes a notch region Q0. The notch region Q0 is adjacent to the second channel region Q2 in the second direction D2 and adjacent to the first channel region Q1 in the third direction D3. The drive transistor TO includes the first gate 32 and the second gate 33. Along the first direction D1, the first gate portion 331, the second gate portion 332, and the third gate portion 321 all overlap with the notch region Q0. At least the third gate portion 321 is electrically connected to a data signal transmission structure 4 in the notch region Q0. The data signal transmission structure 4 is spaced apart from the first active layer 311 of the drive transistor TO in the same layer.

With reference to the preceding description, a shape of the channel region of the drive transistor is designed so that a region where the drive transistor TO is located has a notch region Q0. The notch region Q0 is free of active layers of the drive transistor and can be used to achieve electrical connections between different structures as needed. In this embodiment, the notch region Q0 can be used to achieve an electrical connection between a gate of the drive transistor and the data signal transmission structure 4.

As the name implies, the data signal transmission structure 4 refers to a structure used to transmit data signals. This structure extends from a position where other circuit elements are located to the notch region for an electrical connection with the gate of the drive transistor to transmit a data signal to the gate of the drive transistor, thereby controlling the drive current based on the regulation of the data signal and further controlling light emission brightness of a light-emitting element.

Exemplarily, with reference to FIG. 2 and FIG. 3, a 2T1C pixel circuit, in addition to the drive transistor TO, also includes a first switch transistor T1. A first electrode of the first switch transistor T1 is electrically connected to a data signal line Data, a second electrode of the first switch transistor T1 is electrically connected to the gate of the drive transistor TO, and a gate of the first switch transistor T1 is electrically connected to a scanning signal line Scan. When a scanning signal controls the first switch transistor T1 to turn on, a data signal on the data signal line Data is written to the gate of the drive transistor TO. In this case, the data signal transmission structure 4 can be specifically understood as an extension pattern of the active layer pattern of the first switch transistor T1.

With reference to FIG. 3 and FIG. 6, optionally, the active layer pattern of the first switch transistor T1 and its extension pattern (the data signal transmission structure 4) are spaced apart from the first active layer 311 of the drive transistor TO in the same layer.

As described above, the gate of the drive transistor TO includes at least one of the first gate 32 or the second gate 33, and depending on different configurations of the gate of the drive transistor TO, the structure connected to the data signal transmission structure 4 varies.

With reference to FIG. 6, an example where the drive transistor TO includes both the first gate 32 and the second gate 33 is used for description. In this case, the first gate portion 331, the second gate portion 332, and the third gate portion 321 all overlap with the notch region Q0, and in the first gate portion 331, the second gate portion 332, and the third gate portion 321, at least the third gate portion 321 is electrically connected to the data signal transmission structure 4 in the notch region Q0. In other words, at least the first gate 32 of the first gate 32 and the second gate 33 is electrically connected to the data signal transmission structure 4 to receive a data signal.

Similarly, it can be easily understood that in other embodiments, if the drive transistor TO includes only the first gate 32, the third gate portion 321 overlaps with the notch region Q0 along the first direction D1, and the third gate portion 321 is electrically connected to the data signal transmission structure 4 in the notch region Q0.

In other embodiments, if the drive transistor TO includes only the second gate 33, both the first gate portion 331 and the second gate portion 332 overlap with the notch region Q0 along the first direction D1, and on the basis of an electrical connection between the first gate portion 331 and the second gate portion 332, the first gate portion 331 is also electrically connected to the data signal transmission structure 4 in the notch region Q0.

An example where the drive transistor TO includes both the first gate 32 and the second gate 33 is used as an example below to further describe the configuration of the gates in the drive transistor.

With reference to FIG. 6, as a feasible implementation, optionally, the first gate 32 is electrically connected to the second gate 33. The first gate portion 331 is electrically connected to the third gate portion 321 through a first through hole 211, and the first gate portion 331 is electrically connected to the data signal transmission structure 4 through a second through hole 212. Both the first through hole 211 and the second through hole 212 are located in the notch region Q0.

Specifically, in this embodiment, the first gate 32 is electrically connected to the second gate 33. In this case, the first gate 32 and the second gate 33 are both electrically connected to the data signal transmission structure 4 to receive a data signal. In this manner, the channel control capability can be enhanced, the performance of the drive transistor can be improved, the threshold voltage stability can be optimized, and the reliability of the drive transistor can be ensured, thereby facilitating display quality.

With reference to FIG. 6, the third gate portion 321 in the first gate 32 and the first gate portion 331 in the second gate 33 are electrically connected through the first through hole 211, while the first gate portion 331 and the data signal transmission structure 4 are electrically connected through the second through hole 212. In this manner, the third gate portion 321 is indirectly electrically connected to the data signal transmission structure 4 through hole the first gate portion 331, thereby achieving electrical connections of the first gate 32 and the second gate 33 to the data signal transmission structure 4. This configuration, compared a configuration where the third gate portion 321 is directly electrically connected to the data signal transmission structure 4 through a through hole, can reduce the processing difficulty of the through hole.

FIG. 6 illustrates an example where the first gate portion 331 and the second gate portion 332 are in direct contact and electrically connected to each other. With reference to FIG. 9, in other embodiments, when the second gate portion 332 is parallel to the plane where the substrate 10 is located and the first gate 32 is electrically connected to the second gate 33, the second gate portion 332 may be electrically connected to the third gate portion 321 through a fifth through hole 215, and the third gate portion 321 and the first gate portion 331 are electrically connected through the first through hole 211, thereby allowing the second gate portion 332 to be indirectly electrically connected to the first gate portion 331 through hole the third gate portion 321 and thus reducing the processing difficulty of the through hole.

As another feasible implementation, FIG. 10 is a sectional view of another array substrate taken along line CC′ in FIG. 3, and a corresponding sectional view of the array substrate taken along line BB′ in FIG. 3 refers to FIG. 5. As shown in FIG. 10, optionally, the first gate 32 and the second gate 33 are independently controlled. The third gate portion 321 is electrically connected to the data signal transmission structure 4 through a third through hole 213. The third through hole 213 is located in the notch region Q0 and passes through a layer where the first gate portion 331 is located. The first gate portion 331 is provided with a first opening 3310. The orthographic projection of a region where the third through hole 213 is located on the substrate 10 falls within the range of the orthographic projection of a region where the first opening 3310 is located on the substrate 10.

Specifically, in this embodiment, the first gate 32 and the second gate 33 are independently controlled. In this case, the first gate 32 is electrically connected to the data signal transmission structure 4, and the second gate 33 may be independently connected to a control signal for adjusting a threshold voltage of the drive transistor, thereby providing more flexible device regulation capabilities.

As shown in FIG. 10, the layer where the third gate portion 321 is located is on one side of the layer where the first gate portion 331 is located away from the substrate, and the data signal transmission structure 4 is spaced apart from the first active layer 311 of the drive transistor TO in the same layer and is located on one side of the layer where the first gate portion 331 is located close to the substrate. Therefore, a connection through hole (the third through hole 213) between the third gate portion 321 and the data signal transmission structure 4 needs to pass through the layer where the first gate portion 331 is located. In this embodiment, the first opening 3310 is disposed in the first gate portion 331 so that the orthographic projection of a region where the third through hole 213 is located on the substrate 10 falls within the range of the orthographic projection of a region where the first opening 3310 is located on the substrate 10, thereby ensuring mutual insulation between the third gate portion 321 and the first gate portion 331.

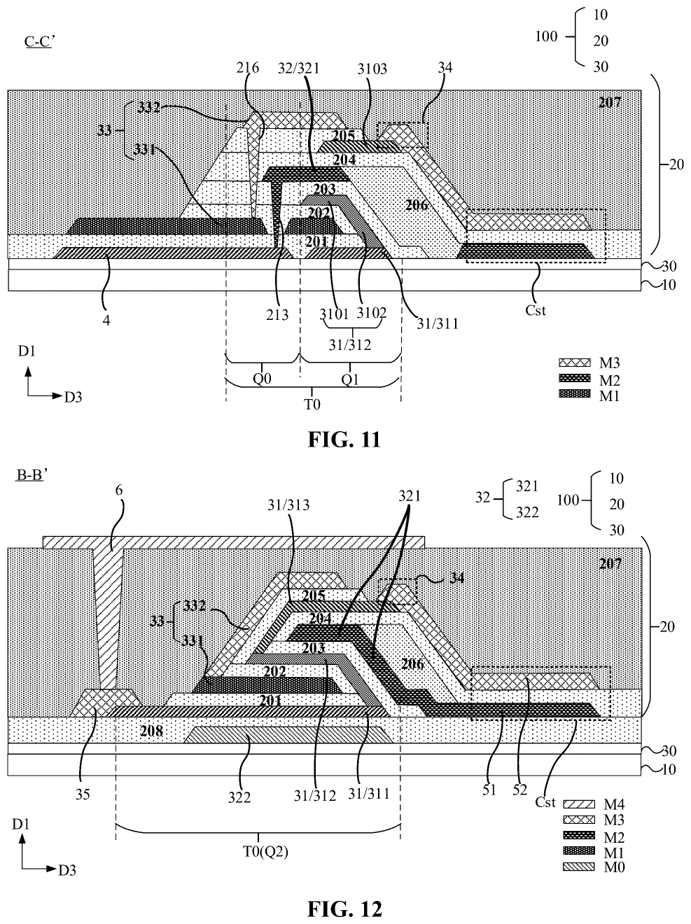

FIG. 10 illustrates an example where the first gate portion 331 and the second gate portion 332 are in direct contact and electrically connected to each other. FIG. 11 is a sectional view of another array substrate taken along line CC′ in FIG. 3, and a corresponding sectional view of the array substrate taken along line BB′ in FIG. 3 refers to FIG. 8. With reference to FIG. 11, in other embodiments, when the second gate portion 332 is parallel to the plane where the substrate 10 is located and the first gate 32 and the second gate 33 are independently controlled, the first gate portion 331 and the second gate portion 332 may be electrically connected through a sixth through hole 216 in the notch region Q0.

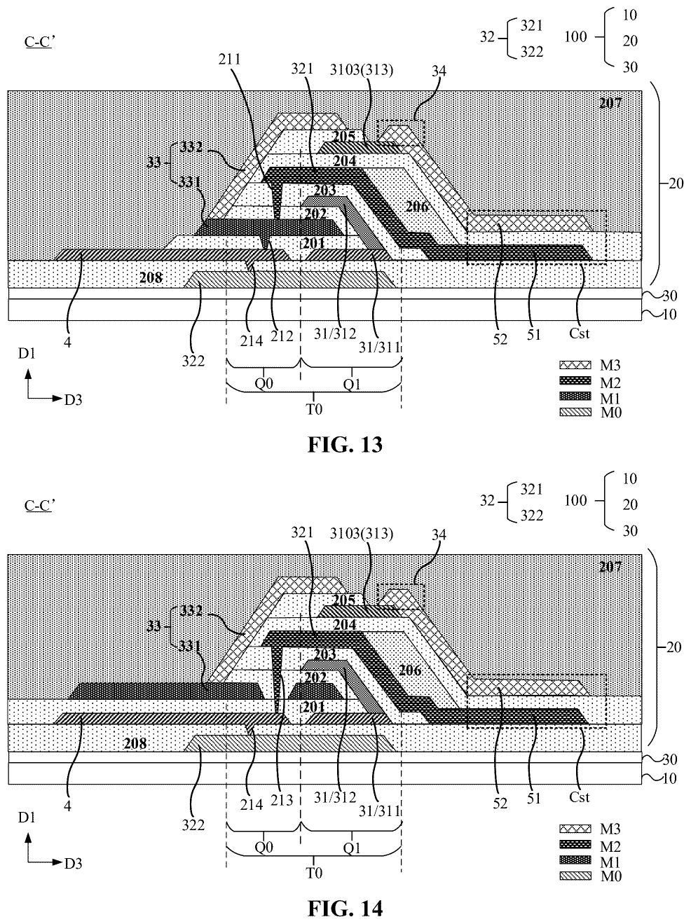

Based on any of the embodiments related to the gate of the drive transistor, FIG. 12 is a sectional view of another array substrate taken along line BB′ in FIG. 3, FIG. 13 is a sectional view of another array substrate taken along line CC′ in FIG. 3 (in FIG. 13, the first gate 32 is electrically connected the second gate 33), and FIG. 14 is a sectional view of another array substrate taken along line CC′ in FIG. 3 (in FIG. 14, the first gate 32 and the second gate 33 are independently controlled). As shown in FIG. 12 to FIG. 14, optionally, the first gate 32 also includes a fourth gate portion 322 located between the first active layer 311 and the substrate 10. The fourth gate portion 322 is electrically connected to the data signal transmission structure 4 through a fourth through hole 214. The fourth through hole 214 is located in the notch region Q0.

Specifically, in this embodiment, the first gate 32 includes the third gate portion 321 and the fourth gate portion 322, both of which are located on the same side of an entire channel layer of the drive transistor. Compared with the preceding embodiments, the addition of the fourth gate portion 322 can further increase the projection area of the first gate 32 on the channel layer of the drive transistor and further enhance the control capability of the first gate 32 over the drive transistor.

As described above, at least the first gate 32 of the first gate 32 and the second gate 33 is electrically connected to the data signal transmission structure 4. Therefore, the fourth gate portion 322 is electrically connected to the data signal transmission structure 4. As shown in FIG. 13, the fourth gate portion 322 may be electrically connected to the data signal transmission structure 4 through the fourth through hole 214 in the notch region Q0.

As shown in FIG. 12, the array substrate 100 also includes a barrier layer 30 located between the substrate 10 and the circuit function layer 20. The arrangement of the barrier layer 30 contributes to ensuring the quality of layers above. The fourth gate portion 322 may be disposed above the barrier layer 30, and a sixth insulating layer 208 is disposed between a layer where the fourth gate portion 322 is located and a layer where the first active layer 311 is located.

With reference to FIG. 5 to FIG. 7, optionally, along the third direction D3, the third active portion 3103 includes a first region S1 at least located in the first channel region Q1; and the first active layer 311 includes a second region S2 located in the second channel region Q2. The orthographic projection of the first region S1 on the substrate 10 and the orthographic projection of the second region S2 on the substrate 10 are oppositely disposed along the third direction D3. The first region S1 is a first electrode lead-out region of the drive transistor TO, and the second region S2 is a second electrode lead-out region of the drive transistor TO.

Specifically, along the third direction D3, the first region S1 and a region of the third active portion 3103 connected to the fourth active portion 3104 are oppositely disposed, and the second region S2 and a region of the first active layer 311 connected to the second active portion 3102 are oppositely disposed, while the second active portion 3102 and the fourth active portion 3104 are located on opposite sides of the first active portion 3101 along the third direction D3. Thus, the orthographic projections of the first region S1 and the second region S2 on the substrate 10 are oppositely disposed along the third direction D3. In general, the first region S1 and the second region S2 are located at two ends of the entire channel layer of the drive transistor.

Regarding the first region S1, it is at least located in the first channel region Q1. Specifically, the first region S1 may be entirely located within the first channel region Q1. Alternatively, a portion of the first region S1 is located in the first channel region Q1, and another portion is located in the second channel region Q2. FIG. 7 illustrates the latter as an example.

One of the first region S1 (first electrode lead-out region) and the second region S2 (second electrode lead-out region) is a source lead-out region, and the other is a drain lead-out region. In other words, one of the first region S1 and the second region S2 is an input terminal of the channel of the drive transistor (hereinafter referred to as an input terminal of the drive transistor), and the other is an output terminal of the channel of the drive transistor (hereinafter referred to as an output terminal of the drive transistor), both used for an electrical connection to other circuit elements or signal lines.

With reference to FIG. 2, in a 2T1C pixel circuit, the input terminal of the drive transistor T0 is coupled to a first voltage signal terminal Elvdd, the output terminal of the drive transistor T0 is coupled to an anode of an LED light-emitting element, and a cathode of the LED light-emitting element is electrically connected to a second voltage signal terminal Elvss. The voltage of the second voltage signal terminal Elvss is less than the voltage of the first voltage signal terminal Elvdd. Other types of pixel circuits follow a similar principle and will be described later.

With reference to FIG. 3, FIG. 5, and FIG. 7, a 2T1C pixel circuit is used as an example. The drive transistor T0 also includes a first electrode 34 and a second electrode 35. The first electrode 34 overlaps with the first region S1 of the third active portion 3103 and is electrically connected to the first voltage signal terminal Elvdd. The second electrode 35 overlaps with the second region S2 of the first active layer 311 and is electrically connected to an anode structure 6. In this case, the first region S1 is the input terminal of the drive transistor, and the second region S2 is the output terminal of the drive transistor.

In other embodiments, the first region S1 may be selected as the output terminal of the drive transistor, and the second region S2 may be selected as the input terminal of the drive transistor, which is not limited by embodiments of the present disclosure. Subsequent descriptions will use the example where the first region S1 is the input terminal of the drive transistor and the second region S2 is the output terminal of the drive transistor.

Regarding the anode structure 6, it should be noted that the array substrate provided by embodiments of the present disclosure may be applied to any type of LED display panel, including but not limited to OLED display panels, micro-LED display panels, and mini-LED display panels. In different types of display panels, the specific structure represented by the anode structure 6 varies. For example, in an OLED display panel, the anode structure 6 may directly serve as an anode of an OLED light-emitting element; in a micro-LED display panel, the anode structure 6 may serve as an anode pad for bonding with an anode of a micro-LED light-emitting element.

With reference to FIG. 5 and FIG. 6, optionally, the array substrate also includes an interlayer insulating layer 206, at least a portion of the interlayer insulating layer 206 is located on one side of the third insulating layer 203 away from the second active portion 3102, and the fourth insulating layer 204 covers the interlayer insulating layer 206. Along the first direction D1, the thickness of the interlayer insulating layer 206 is greater than the thickness of the third insulating layer 203.

The interlayer insulating layer 206 can provide support and insulation. The material of the interlayer insulating layer 206 may be an organic material or an inorganic material, which is not limited by embodiments of the present disclosure. A thicker interlayer insulating layer 206 is disposed at least on one side of the third insulating layer 203 away from the second active portion 3102, and the fourth insulating layer 204 covers the interlayer insulating layer 206. In this manner, an increase in the area of a portion of the fourth insulating layer 204 parallel to the plane where the substrate 10 is located is facilitated, a fabrication platform for the third active portion 3103 is increased, and it is ensured that the third active portion 3103 is fabricated on a relatively flat plane, thereby ensuring product reliability.

With continued reference to FIG. 5, optionally, the drive transistor T0 includes a first gate 32, and the first gate 32 includes a third gate portion 321. A part of the third gate portion 321 is located between the third insulating layer 203 and the fourth insulating layer 204, the third insulating layer 203 and the fourth insulating layer 204 are located between the first active portion 3101 and the third active portion 3103, another portion of the third gate portion 321 is located between the interlayer insulating layer 206 and the third insulating layer 203. Along the first direction D1, the interlayer insulating layer 206 includes a first surface F1 and a second surface F2 that are opposite to each other, a first portion of the third gate portion 321 includes a third surface F3 and a fourth surface F4 that are opposite to each other, the second surface F2 is located on one side of the first surface F1 away from the substrate 10, the fourth surface F4 is located on one side of the third surface F3 away from the substrate 10, and the second surface F2 is flush with the fourth surface F4. The first portion of the third gate portion 321 is a part of the third gate portion 321 located between the first active portion 3101 and the third active portion 3103.

The first portion of the third gate portion 321 may be specifically understood as a part of the third gate portion 321 parallel to the plane where the substrate 10 is located.

It should be noted that the design of the interlayer insulating layer 206 in this embodiment is applicable to cases where the drive transistor T0 includes the first gate 32. Specifically, the cases may be that the drive transistor T0 includes only the first gate 32 or the drive transistor T0 includes both the first gate 32 and the second gate 33. FIG. 5 illustrates the latter as an example. The case where the drive transistor T0 includes only the first gate 32 is similar, differing only in the absence of the second gate 33. Details are not repeated here.

When the drive transistor T0 includes the first gate 32, the third gate portion 321 in the first gate 32 may extend from a region between the first active portion 3101 and the third active portion 3103 to one side of the third insulating layer 203 away from the second active portion 3102. As can be seen from FIG. 5, limited by the length of the first active portion 3101 in the third direction D3, the length of a horizontal portion of the third gate portion 321 in the third direction D3 is limited. In this embodiment, the interlayer insulating layer 206 is disposed on one side of the third gate portion 321 away from the second active portion 3102 so that a top surface (the second surface F2) of the interlayer insulating layer 206 is flush with a top surface (the fourth surface F4) of the third gate portion 321, and the fourth insulating layer 204 covers the top surface of the interlayer insulating layer 206 and the top surface of the third gate portion 321. Thus, the length of a horizontal portion of the fourth insulating layer 204 in the third direction D3, the area of a part of the fourth insulating layer 204 parallel to the plane where the substrate 10 is located, and a fabrication platform for the third active portion 3103 are increased, and it is ensured that the third active portion 3103 is fabricated on a relatively flat plane, thereby ensuring product reliability.

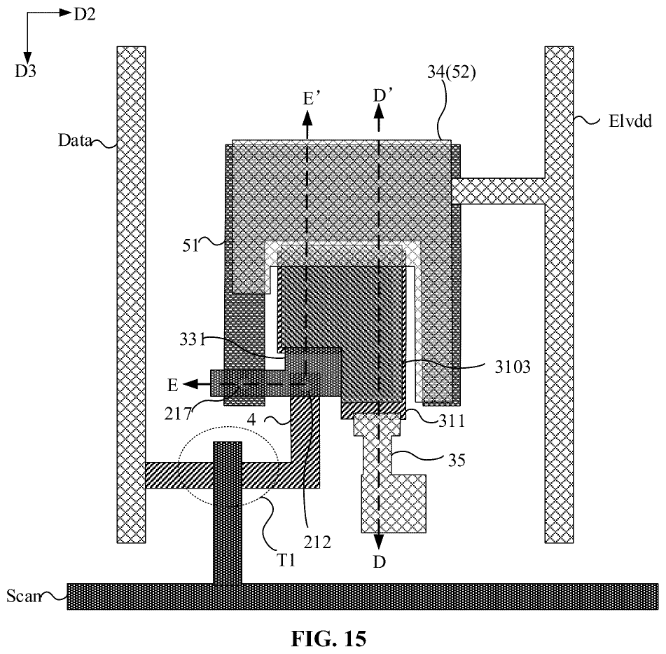

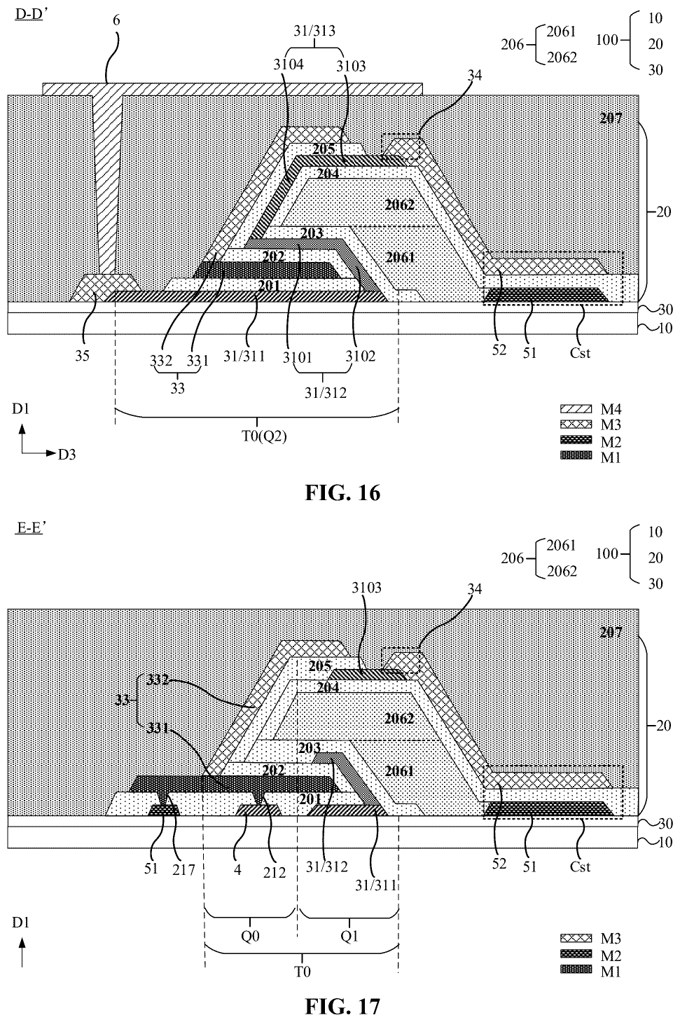

FIG. 15 is another schematic diagram illustrating part of the layer structure of an array substrate according to an embodiment of the present disclosure, specifically showing a layout structure corresponding to a pixel circuit shown in FIG. 2. FIG. 16 is a sectional view of an array substrate taken along line DD′ in FIG. 15. FIG. 17 is a sectional view of an array substrate taken along line EE′ in FIG. 15. As shown in FIG. 15 to FIG. 17, optionally, the interlayer insulating layer 206 is located between the third insulating layer 203 and the fourth insulating layer 204, and the interlayer insulating layer 206 is in contact with the third insulating layer 203 and the fourth insulating layer 204. Along the first direction D1, the interlayer insulating layer 206 includes a first insulating portion 2061 and a second insulating portion 2062. The first insulating portion 2061 is located on one side of the third insulating layer 203 away from the second active portion 3102. The second insulating portion 2062 is located on one side of the fourth insulating layer 204 away from the third active layer 313, and a part of the second insulating portion 2062 is located between the first active portion 3101 and the third active portion 3103.

This embodiment is applicable to a case where the drive transistor T0 includes only the second gate 33. As shown in FIG. 17, in this case, the first gate portion 331 may be electrically connected to the data signal transmission structure 4 through a second through hole 212 located in the notch region Q0.

When the drive transistor T0 includes only the second gate 33, the interlayer insulating layer 206 is surrounded by the third insulating layer 203 and the fourth insulating layer 204. In this embodiment, the thickness of the interlayer insulating layer 206 is further increased. Specifically, a portion of the interlayer insulating layer 206 (the first insulating portion 2061) is located on one side of the third insulating layer 203 away from the second active portion 3102, and another portion (the second insulating portion 2062) is located on one side of the fourth insulating layer 204 away from the third active layer 313. Moreover, a part of the second insulating portion 2062 is located between the first active portion 3101 and the third active portion 3103 (the three overlap along the first direction D1), and another portion of the second insulating portion 2062 overlaps with the first insulating portion 2061 along the first direction D1. In this manner, the length of the fourth active portion 3104 between the first active portion 3101 and the third active portion 3103 can be increased. This allows a further reduction of the projection area of the channel region of the drive transistor on the substrate while a constant total channel length is maintained, thereby reducing the area of the pixel circuit.

In summary, the preceding embodiments provide a detailed description of a design of the region where the drive transistor in the pixel circuit is located, and the preceding design can be applied to any type of pixel circuit.

A 2T1C pixel circuit is still used as an example below to further describe the connection relationship between other structures in the pixel circuit and the drive transistor.

With reference to FIG. 3 to FIG. 6, optionally, the circuit function layer 20 also includes a storage capacitor Cst, and the storage capacitor Cst includes a first capacitor plate 51 and a second capacitor plate 52 that are oppositely disposed and insulated from each other. Along the first direction D1, a region where the storage capacitor Cst is located does not overlap with the channel region Q. At least a portion of the orthographic projection of the storage capacitor Cst on the substrate 10 is located on one side of the orthographic projection of the second active portion 3102 on the substrate 10 away from the orthographic projection of the fourth active portion 3104 on the substrate 10.

With reference to FIG. 2, in the pixel circuit, the storage capacitor Cst is typically connected between the gate of the drive transistor T0 and the first voltage signal terminal Elvdd to maintain stability of the gate voltage of the drive transistor T0 and ensure continuity and consistency of pixel light emission.

The first capacitor plate 51 is electrically connected to the gate of the drive transistor T0, where the gate specifically refers to a gate that receives a data signal.

Specifically, when the drive transistor T0 includes only one gate, the first capacitor plate 51 is electrically connected to this gate. For example, in FIG. 15 to FIG. 17, the drive transistor T0 includes only a second gate 33, and the first capacitor plate 51 is electrically connected to the second gate 33.

Additionally, when the drive transistor T0 includes both a first gate 32 and a second gate 33, at least the first gate 32 is used to receive a data signal. Therefore, the first capacitor plate 51 is at least electrically connected to the first gate 32. Specifically, based on the preceding explanation, if the first gate 32 is electrically connected to the second gate 33, the first capacitor plate 51 is electrically connected to both the first gate 32 and the second gate 33; if the first gate 32 and the second gate 33 are independently controlled, the first capacitor plate 51 is electrically connected only to the first gate 32.

The second capacitor plate 52 is electrically connected to the first voltage signal terminal Elvdd, and the input terminal of the drive transistor T0 is coupled to the first voltage signal terminal Elvdd. Therefore, the second capacitor plate 52 is coupled to the input terminal of the drive transistor T0.

With reference to FIG. 7, as described above, the first region S1 of the third active portion 3103 may serve as an input terminal of the drive transistor, the second region S2 of the first active layer 311 may serve as an output terminal of the drive transistor, and projection regions of the first region S1 of the third active portion 3103 and the fourth active portion 3104 on the substrate are oppositely disposed along the third direction D3. In this embodiment, at least a part of the orthographic projection of the storage capacitor Cst on the substrate 10 is located on one side of the orthographic projection of the second active portion 3102 on the substrate 10 away from the orthographic projection of the fourth active portion 3104 on the substrate 10 so that an electrical connection between the second capacitor plate 52 of the storage capacitor Cst and the input terminal of the drive transistor is facilitated, and design complexity can be reduced.

Additionally, the channel region Q of the drive transistor includes multiple stacked active layers 31, and gate metal and other structures are disposed between adjacent active layers. Therefore, in this embodiment, the region where the storage capacitor Cst is located does not overlap with the channel region Q along the first direction D1 so that interference between the storage capacitor Cst and the drive transistor T0 can be avoided, and it is also convenient to set the capacitance value as needed by controlling the size of the storage capacitor, thereby reducing the difficulty of design and process.

With reference to FIG. 3, the region where the storage capacitor is located may semi-surround the channel region. Thus, the area of the storage capacitor can be increased.

With reference to FIG. 5 and FIG. 6, optionally, the fourth insulating layer 204 extends to the region where the storage capacitor Cst is located and serves as a capacitor insulating layer between the first capacitor plate 51 and the second capacitor plate 52.

With reference to FIG. 5 to FIG. 7, for a 2T1C pixel circuit, when the drive transistor T0 includes the first gate 32, optionally, the drive transistor also includes a first electrode 34, and the first electrode 34 overlaps with the first region S1 of the third active portion 3103. The first capacitor plate 51 is electrically connected to the third gate portion 321, and the second capacitor plate 52 is electrically connected to the first electrode 34.

Specifically, with reference to FIG. 6, the first electrode 34 abuts the first region S1 and is electrically connected to the second capacitor plate 52 through a first connection portion 221, thereby achieving an electrical connection between the input terminal of the drive transistor and the second capacitor plate 52 of the storage capacitor. With reference to FIG. 3, the first electrode 34, the second capacitor plate 52, and the first connection portion 221 may be integrally formed.

With reference to FIG. 6, when the drive transistor T0 includes the first gate 32, the first capacitor plate 51 may be electrically connected to the third gate portion 321 through a second connection portion 222. Optionally, the first capacitor plate 51, the second connection portion 222, and the third gate portion 321 are integrally formed.

It should be noted that the design of the first capacitor plate 51 in the storage capacitor Cst in this embodiment is applicable to cases where the drive transistor T0 includes the first gate 32. Specifically, the cases may be that the drive transistor T0 includes only the first gate 32 or the drive transistor T0 includes both the first gate 32 and the second gate 33. FIG. 5 and FIG. 6 illustrate the latter as an example. The case where the drive transistor T0 includes only the first gate 32 is similar, differing only in the absence of the second gate 33. Details are not repeated here.

With reference to FIG. 6, for the case where the drive transistor T0 includes the first gate 32, in a 2T1C pixel circuit, the provision of a thicker interlayer insulating layer 206 can also avoid the presence of coupling capacitance between one side portion of the third gate portion 321 and the first connection portion 221, thereby ensuring controllability of the region where the storage capacitor Cst is located and the capacitance value.

In other embodiments, with reference to FIG. 15 to FIG. 17, the drive transistor T0 may include only the second gate 33. In this case, the first gate portion 331 may be disposed in a first metal layer M1, the first capacitor plate 51 may be disposed in a second metal layer M2, and the first electrode 34 and the second capacitor plate 52 may be disposed in a third metal layer M3. Optionally, projections of the first gate portion 331 and the first capacitor plate 51 overlap along the first direction D1 and are electrically connected through a seventh through hole 217. The seventh through hole 217 may be disposed outside the region where the drive transistor T0 is located.

With reference to FIG. 16 and FIG. 17, optionally, a plane where the first capacitor plate 51 is located and a plane where the second capacitor plate 52 is located are both parallel to the plane where the substrate 10 is located. With this arrangement, the manufacturing process is relatively simple.

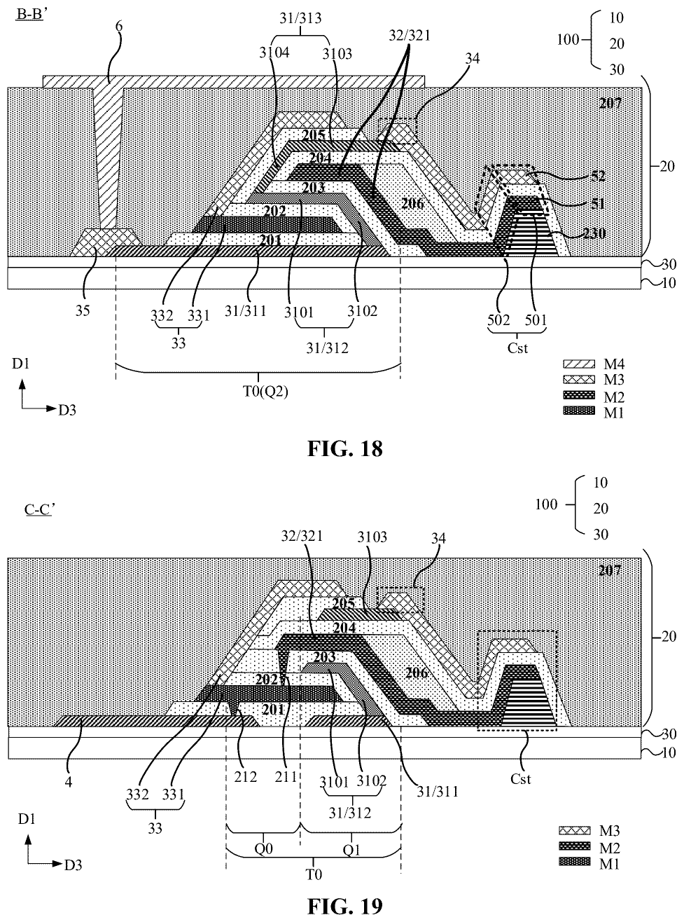

FIG. 18 is a sectional view of another array substrate taken along line BB′ in FIG. 3. FIG. 19 is a sectional view of another array substrate taken along line CC′ in FIG. 3. As shown in FIG. 18 and FIG. 19, optionally, the storage capacitor Cst includes a first capacitor portion 501 and a second capacitor portion 502, a plane where the first capacitor portion 501 is located is parallel to the plane where the substrate 10 is located, and a plane where the second capacitor portion 502 is located intersects the plane where the substrate 10 is located. A support pillar 230 is disposed between the first capacitor portion 501 and the substrate 10.

The plane where the first capacitor portion 501 is located can be specifically understood as a plane where the first capacitor plate 51 and the second capacitor plate 52 in the first capacitor portion 501 are located, and in the first capacitor portion 501, the planes where the first capacitor plate 51 and the second capacitor plate 52 are located are parallel to the plane where the substrate is located. Similarly, the plane where the second capacitor portion 502 is located can be specifically understood as a plane where the first capacitor plate 51 and the second capacitor plate 52 in the second capacitor portion 502 are located, and in the second capacitor portion 502, the planes where the first capacitor plate 51 and the second capacitor plate 52 are located intersect the plane where the substrate is located.

The support pillar 230 is used to support the first capacitor portion 501. The material of the support pillar 230 may be an organic material or an inorganic material, which is not limited by embodiments of the present disclosure. In a specific embodiment, the support pillar 230 may be formed by stacking multiple insulating layers.

Under the condition that the facing area and spacing between the first capacitor plate 51 and the second capacitor plate 52 remain unchanged, compared to a case where planes where the entire first capacitor plate 51 and the entire second capacitor plate 52 are located are both parallel to the plane where the substrate 10 is located, the storage capacitor Cst in this embodiment includes a first capacitor portion 501 parallel to the substrate and a second capacitor portion 502 intersecting the substrate, and a support pillar 230 is disposed between the first capacitor portion 501 and the substrate 10. In this manner, the projection area of the storage capacitor on the substrate can be further reduced, thereby further reducing the area of the pixel circuit.

In summary, a detailed description of the design of a drive transistor and the connection relationship between the drive transistor and a storage capacitor is given in the preceding embodiments by using a 2T1C pixel circuit as an example. It should be noted that in the preceding embodiments, in addition to the connection manner between the storage capacitor and the drive transistor, the design of the storage capacitor, such as the region where the storage capacitor is located, layer positions of the first capacitor plate and the second capacitor plate, and their parallel or intersecting relationship with the plane where the substrate is located, is equally applicable to other pixel circuits and will not be repeated hereafter.

A 7T1C pixel circuit is used as an example below to further briefly describe the technical solution of the embodiments of the present disclosure, with similarities not repeated here.

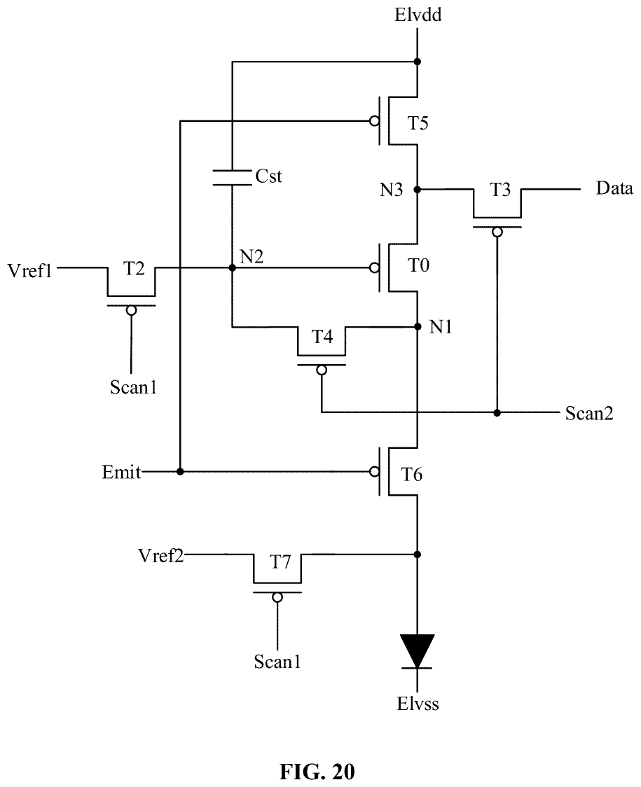

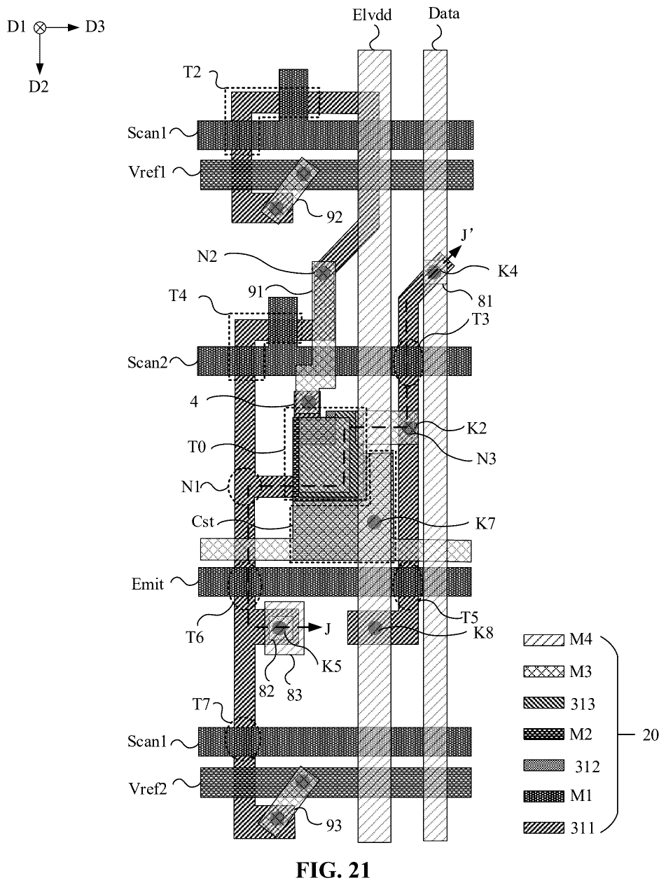

Exemplarily, FIG. 20 is a schematic diagram of a 7T1C pixel circuit, and FIG. 21 is a schematic diagram illustrating the layer structure of another array substrate according to an embodiment of the present disclosure, specifically showing a layout structure corresponding to the pixel circuit shown in FIG. 20. As shown in FIG. 20 and FIG. 21, in a circuit function layer 20, a pixel circuit includes a drive transistor T0, an initialization transistor T2, a data write transistor T3, a threshold compensation transistor T4, a first light emission control transistor T5, a second light emission control transistor T6, a reset transistor T7, and a storage capacitor Cst, which are connected as shown to form a 7T1C pixel circuit. The specific operating principle is not detailed here.

As shown in FIG. 21, the circuit function layer 20 includes a layer where a first active layer 311 is located, a first metal layer M1, a layer where a second active layer 312 is located, a second metal layer M2, a layer where a third active layer 313 is located, a third metal layer M3, and a fourth metal layer M4. The transistors and the storage capacitor in the pixel circuit are formed in these layers.

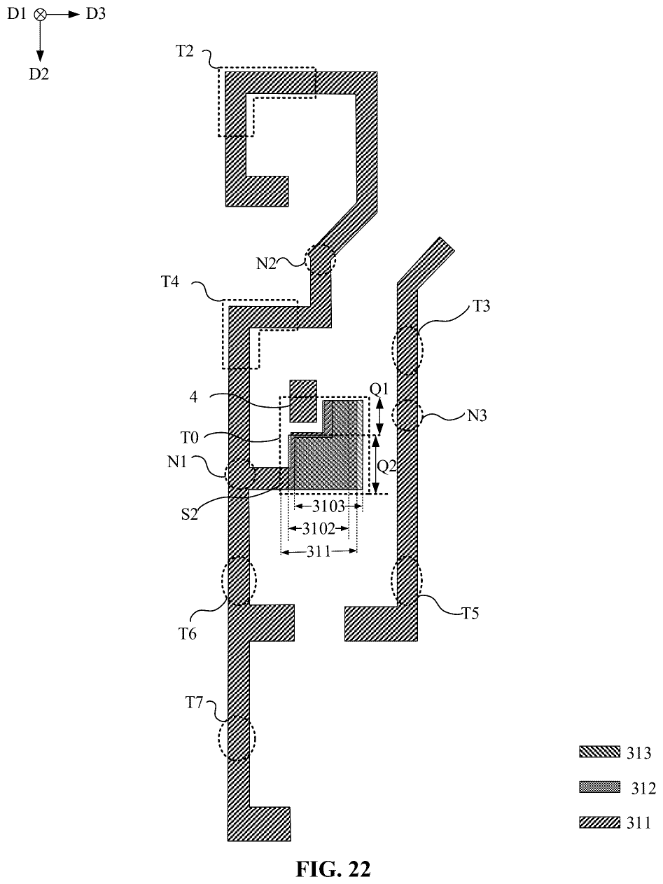

FIG. 22 is a schematic diagram illustrating a stacked structure of layers where a first active layer, a second active layer, and a third active layer are located in FIG. 21. As shown in FIG. 21 and FIG. 22, in addition to the first active layer 311 of the drive transistor T0, the layer where the first active layer 311 is located also includes active layer patterns of the initialization transistor T2, the data write transistor T3, the threshold compensation transistor T4, the first light emission control transistor T5, the second light emission control transistor T6, and the reset transistor T7, as well as a data signal transmission structure 4. A second region S2 (output terminal) of the first active layer 311 of the drive transistor T0, an input terminal of the active layer pattern of the threshold compensation transistor T4, and an input terminal of the active layer pattern of the second light emission control transistor T6 are connected to a first node N1. An output terminal of the active layer pattern of the threshold compensation transistor T4 and an output terminal of the active layer pattern of the initialization transistor T2 are connected to a second node N2, and the second node N2 is also electrically connected to the data signal transmission structure 4 through a first bridge structure 91 located in the third metal layer M3. The data signal transmission structure 4 extends into a notch region of a region where the drive transistor T0 is located to facilitate an electrical connection with a gate of the drive transistor. The active layer pattern of the data write transistor T3 is spaced apart from the first active layer 311 of the drive transistor T0 in the same layer. An output terminal of the active layer pattern of the data write transistor T3 and an output terminal of the first light emission control transistor T5 are connected to a third node N3, and the third node N3 is electrically connected to a first electrode 34 of the drive transistor T0 (located in the third metal layer M3) through a through hole. The layers where the second active layer 312 and the third active layer 313 are located include only the active layers of the drive transistor. For ease of illustration, FIG. 22 only illustrates a first active portion 3101 in the second active layer 312 and a third active portion in the third active layer 313. The design of the active layers of the drive transistor is detailed in the preceding description and is not repeated here.

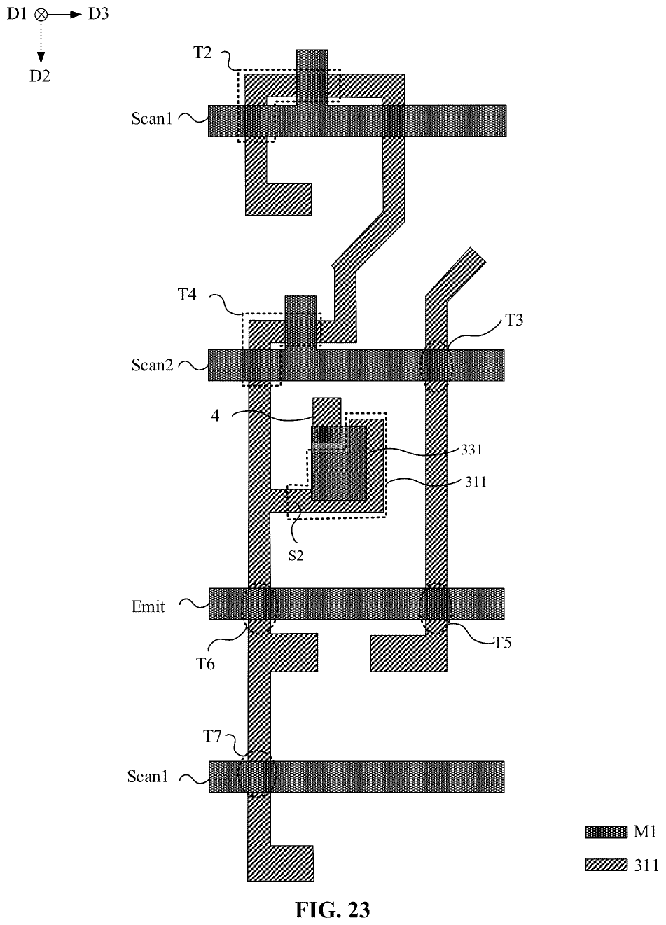

FIG. 23 is a schematic diagram illustrating a stacked structure of a layer where a first active layer is located and a first metal layer in FIG. 21. As shown in FIG. 21 and FIG. 23, the first metal layer M1 includes a first scanning line Scan1, a second scanning line Scan2, a light emission control signal line Emit, and a first gate portion 331 of the drive transistor T0. The first gate portion 331 overlaps with the first active layer 311 and the notch region. With reference to the preceding description, whether the first gate portion 331 is electrically connected to the data signal transmission structure 4 may be set as needed. FIG. 23 illustrates an example where the first gate portion 331 is connected to the data signal transmission structure 4 through a via.

Additionally, a region where a pixel circuit is located may include two first scanning lines Scan1. One first scanning line Scan1 overlaps with the active layer pattern of the initialization transistor T2 to control the on-off state of the initialization transistor T2, and the other first scanning line Scan1 overlaps with the active layer pattern of the reset transistor T7 to control the on-off state of the reset transistor T7. The second scanning line Scan2 overlaps with active layer patterns of both the data write transistor T3 and the threshold compensation transistor T4 to control the on-off states of the data write transistor T3 and the threshold compensation transistor T4. The light emission control signal line Emit overlaps with active layer patterns of both the first light emission control transistor T5 and the second light emission control transistor T6 to control the on-off states of the first light emission control transistor T5 and the second light emission control transistor T6. The first scanning line Scan1, the second scanning line Scan2, and the light emission control signal line Emit all extend along the third direction D3, are arranged in parallel and spaced apart along the second direction D2, and are spaced apart from the first gate portion 331 in the same layer so that gates of each switch transistor are spaced apart from the first gate portion 331 of the drive transistor in the same layer. For example, a gate of the data write transistor T3 is spaced apart from the first gate portion 331 in the same layer.

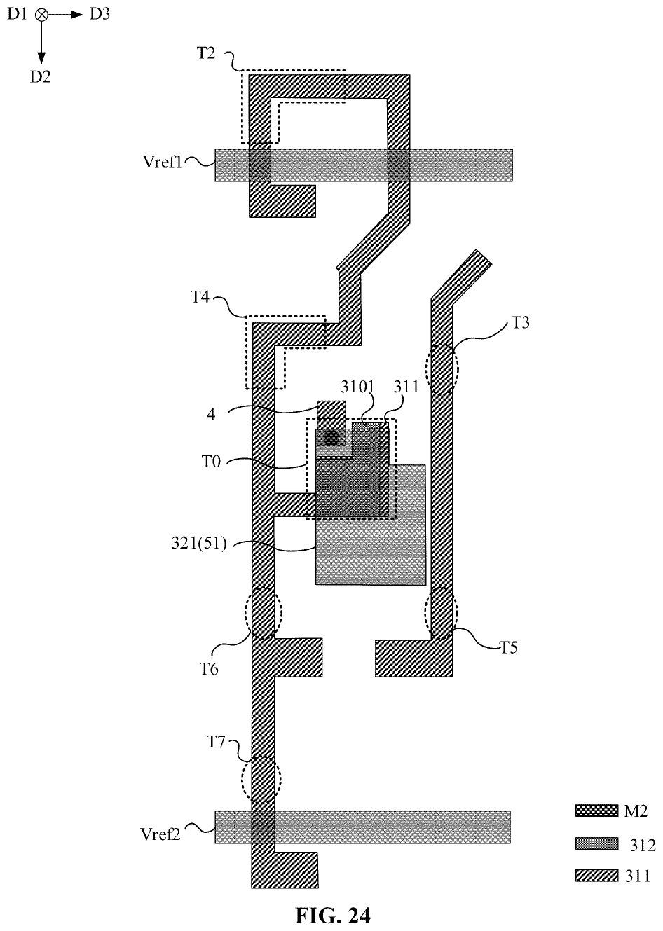

FIG. 24 is a schematic diagram illustrating a stacked structure of a layer where a first active layer is located, a layer where a second active layer is located, and a second metal layer in FIG. 21. As shown in FIG. 21 and FIG. 24, the second metal layer M2 includes an initialization signal line Vref1, a reset signal line Vref2, a third gate portion 321, and a first capacitor plate 51 of the storage capacitor. The third gate portion 321 overlaps with the channel region of the drive transistor and the notch region and is electrically connected to the data signal transmission structure 4. The specific connection manner may refer to the description above. The third gate portion 321 and the first capacitor plate 51 are electrically connected and may be integrally formed.

Additionally, the initialization signal line Vref1 is used to transmit an initialization signal to the initialization transistor T2 to initialize the gate potential of the drive transistor. Optionally, the initialization signal line Vref1 and the initialization transistor T2 may be electrically connected through a second bridge structure 92 located in the third metal layer M3. The reset signal line Vref2 is used to transmit a reset signal to the reset transistor T7 to reset the anode voltage of a light-emitting element. Optionally, the reset signal line Vref2 and the reset transistor T7 may be electrically connected through a third bridge structure 93 located in the third metal layer M3.

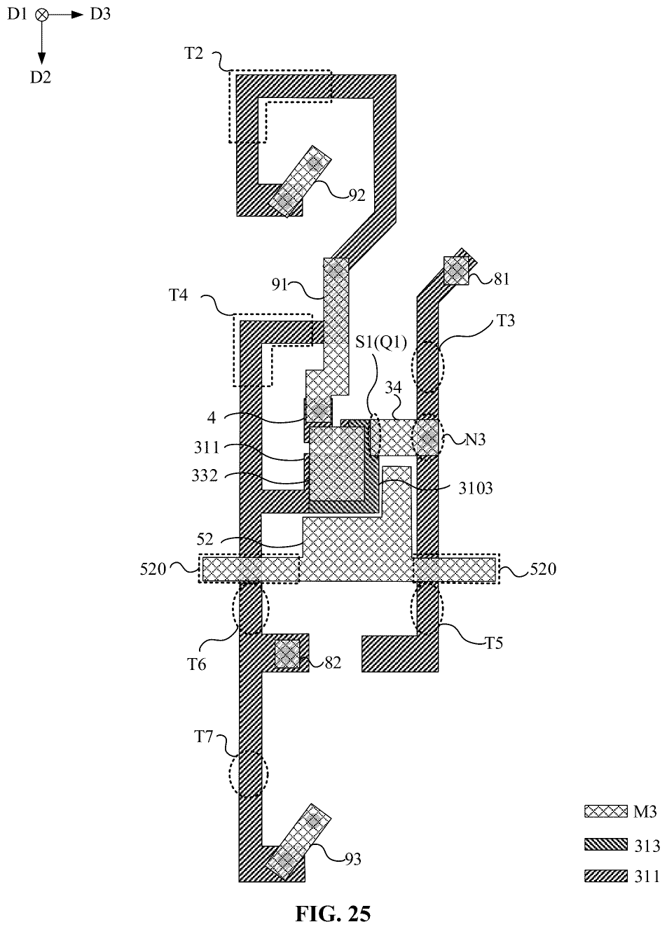

FIG. 25 is a schematic diagram illustrating a stacked structure of a layer where a first active layer is located, a layer where a third active layer is located, and a third metal layer in FIG. 21. As shown in FIG. 21, FIG. 22, and FIG. 25, in addition to the first bridge structure 91, the second bridge structure 92, and the third bridge structure 93 mentioned above, the third metal layer M3 also includes a second gate portion 332 and a first electrode 34 of the drive transistor, a second capacitor plate 52 of the storage capacitor, and a capacitor extension portion 520. The second gate portion 332 is electrically connected to the first gate portion 331 in the first metal layer M1. The first electrode 34 overlaps with a first region S1 of a third active portion 3103. The second capacitor plate 52 is spaced apart from the first electrode 34 in the same layer. The capacitor extension portion 520 is located on opposite sides of the second capacitor plate 52 along the third direction D3 and is connected to the second capacitor plate 52. The capacitor extension portion 520 is provided so that second capacitor plates 52 in pixel circuits in the same row along the third direction D3 can be connected, which facilitates voltage uniformity of a first voltage signal (Elvdd).

It should be noted that FIG. 25 illustrates an example where the first region S1 of the third active portion 3103 is located in the first channel region Q1. In other embodiments, the first region S1 may be partially located in the first channel region Q1 and partially in the second channel region Q2. In this manner, the overlapping area between the first electrode 34 and the third active portion 3103 can be increased, as long as a spacing is maintained between the second capacitor plate 52 and structures in the same layer, such as the first electrode 34 and the second gate portion 332.

Additionally, with reference to FIG. 21, the fourth metal layer M4 includes a first voltage signal line (Elvdd) and a data signal line Data, both of which extend along the second direction D2 and are spaced apart along the third direction D3. A first terminal (e.g. input terminal) of the active layer pattern of the data write transistor T3 is electrically connected to the data signal line Data through a through hole, and a second terminal (e.g. output terminal) of the active layer pattern of the data write transistor is electrically connected to the first electrode 34 of the drive transistor T0 through a through hole. Additionally, the first voltage signal line (Elvdd) is electrically connected to the second capacitor plate 52 of the storage capacitor through a through hole.

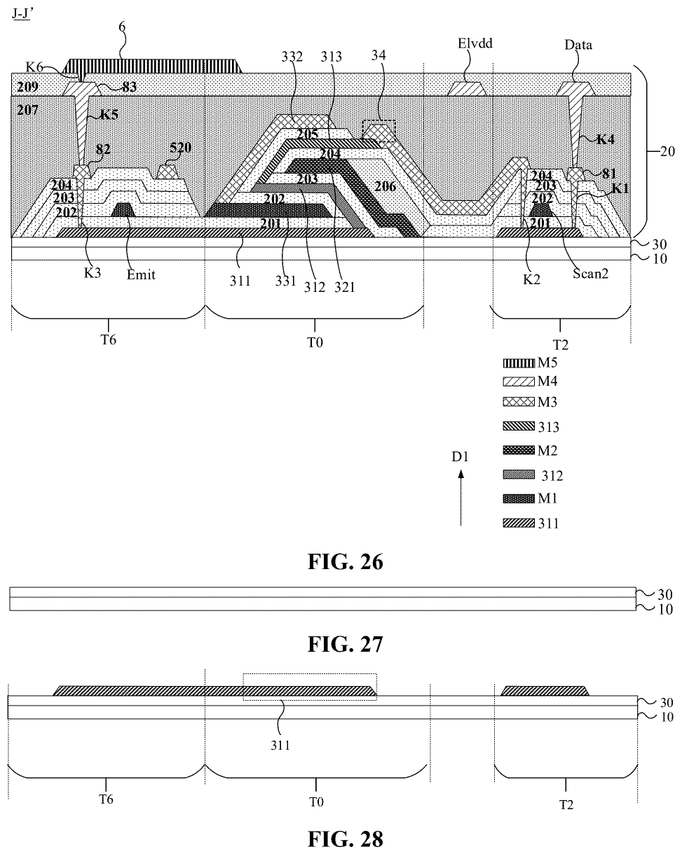

Exemplarily, FIG. 26 is a sectional view of an array substrate taken along line JJ′ in FIG. 21. As shown in FIG. 21, FIG. 25, and FIG. 26, optionally, the circuit function layer 20 also includes a first planarization layer 207, a second planarization layer 209, and a fifth metal layer M5. The first planarization layer 207 is located on one side of the third metal layer M3 away from the substrate 10. The fourth metal layer M4 is located on one side of the first planarization layer 207 away from the substrate 10. The fifth metal layer M5 is located on one side of the second planarization layer 209 away from the substrate 10. An anode structure 6 is located in the fifth metal layer M5. The third metal layer M3 also includes a first adapter structure 81 and a second adapter structure 82. The fourth metal layer M4 also includes a third adapter structure 83. A first terminal of the data write transistor T3 is electrically connected to the first adapter structure 81 through an eighth through hole K1, and the first adapter structure 81 is electrically connected to the data signal line Data through an eleventh through hole K4. A second terminal of the data write transistor T3 is electrically connected to the first electrode 34 of the drive transistor T0 through a ninth through hole K2. An output terminal of the second light emission control transistor T6 is electrically connected to the second adapter structure 82 through a tenth through hole K3. The second adapter structure 82 is electrically connected to the third adapter structure 83 through a twelfth through hole K5. The third adapter structure 83 is electrically connected to the anode structure 6 through a thirteenth through hole K6.

In this embodiment, a first adapter structure 81 and a second adapter structure 82 are disposed in the third metal layer M3, two planarization layers are disposed on one side of the third metal layer M3 away from the substrate 10, and the first voltage signal line (Elvdd), the data signal line Data, and the third adapter structure 83 are arranged between the two planarization layers. In this manner, the second planarization layer 209 can protect the first voltage signal line (Elvdd) and the data signal line Data, flatness of layers below the anode structure 6 can be ensured, and processing difficulty of through holes can be reduced, thereby ensuring product reliability. Exemplarily, the first planarization layer 207 and the second planarization layer 209 may be formed of organic materials.

In summary, the technical solution of the embodiments of the present disclosure is described in detail in the preceding embodiments based on a 2T1C pixel circuit and a 7T1C pixel circuit. Exemplarily, FIG. 27 to FIG. 44 are sectional views illustrating a preparation process corresponding to an array substrate shown in FIG. 26. The preparation method of the array substrate is briefly described using the structure shown in FIG. 26 as an example.

As shown in FIG. 27, in a first step, a barrier layer 30 is prepared on the substrate 10 using a Chemical Vapor Deposition (CVD) process. Optionally, the barrier layer 30 includes a SiNx layer and a SiOx layer stacked from bottom to top. The SiNx layer can be used to block impurity ions in the substrate. The SiOx layer can match the lattice of an active layer (such as P—Si) and provide thermal insulation during a subsequent excimer laser annealing (ELA) process.

As shown in FIG. 28, in a second step, a layer of monocrystalline silicon is prepared on the barrier layer using a CVD process, then the monocrystalline silicon is converted to polycrystalline silicon through an ELA process, and finally the polycrystalline silicon is etched to form a desired pattern, as shown in FIG. 22, where the layer where the first active layer 311 is located includes active layer patterns of channels of transistors. Exemplarily, the polycrystalline silicon may be patterned using dry etching, etching gases may be Cl₂ and SF₆, and the etching amount may be controlled by the etching time.

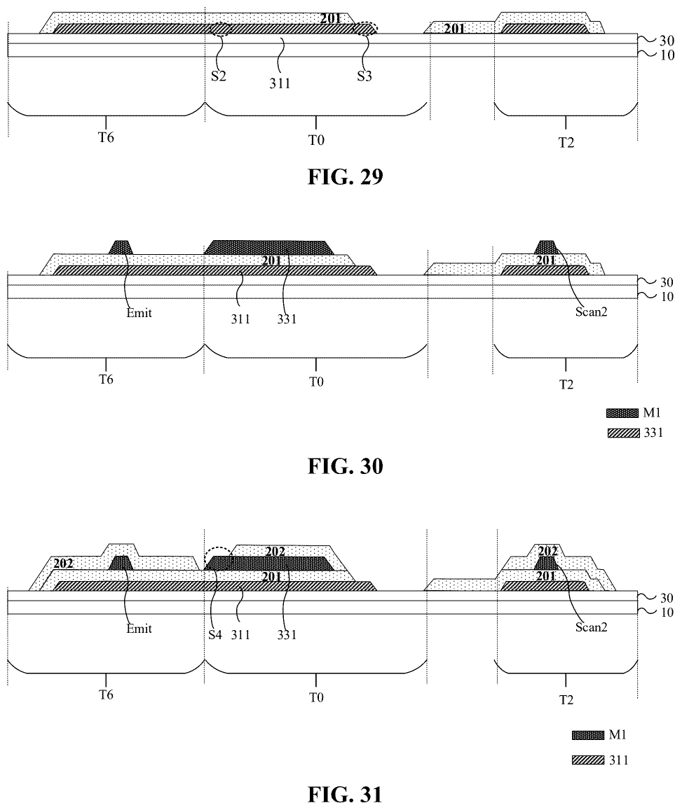

As shown in FIG. 29, in a third step, a first insulating layer is first prepared on one side of the layer where the first active layer 311 is located away from the substrate 10 using a CVD process, and then the insulating layer is etched to form a first insulating layer 201 with a specific pattern. In this embodiment, the first insulating layer 201 exposes a third region S3 of the first active layer 311 of the drive transistor T0 to facilitate a subsequent connection between the first active layer 311 and the second active layer 312 through the third region S3. Exemplarily, the material of the first insulating layer 201 may be SiOx. The first insulating layer 201 may be patterned using dry etching. Etching gases may be CF₄, CHF₃, SF₆, and Ar. The etching amount may be controlled by the etching time. Other insulating layers of the same material may also use this etching method, which is not repeated hereafter.

As shown in FIG. 30, in a fourth step, a first metal layer is prepared on the first insulating layer 201 using a Physical Vapor Deposition (PVD) process, and then the metal layer is etched to form a first metal layer M1 with a specific pattern. As described above, the first metal layer M1 includes patterns such as a first scanning line Scan1, a second scanning line Scan2, a light emission control signal line Emit, and a first gate portion 331 of the drive transistor T0. Exemplarily, the material of the first metal layer M1 may be at least one of Al, Cu, and Mo, and the first metal layer may be patterned using dry etching. Different etching gases may be used depending on the metal. For example, Mo may be etched using gases such as Cl₂ and SF₆. Other metal layers of the same material may also use this etching method, which is not repeated hereafter.

As shown in FIG. 31, in a fifth step, a second insulating layer is prepared on one side of the first metal layer M1 away from the substrate 10 using a CVD process, with a material such as SiOx, and then the insulating layer is etched to form a second insulating layer 202 with a specific pattern. In this embodiment, the second insulating layer 202 exposes a fourth region S4 of the first gate portion 331 of the drive transistor T0 to facilitate a subsequent direct contact and electrical connection between the first gate portion 331 and a second gate portion 332 through the fourth region S4.

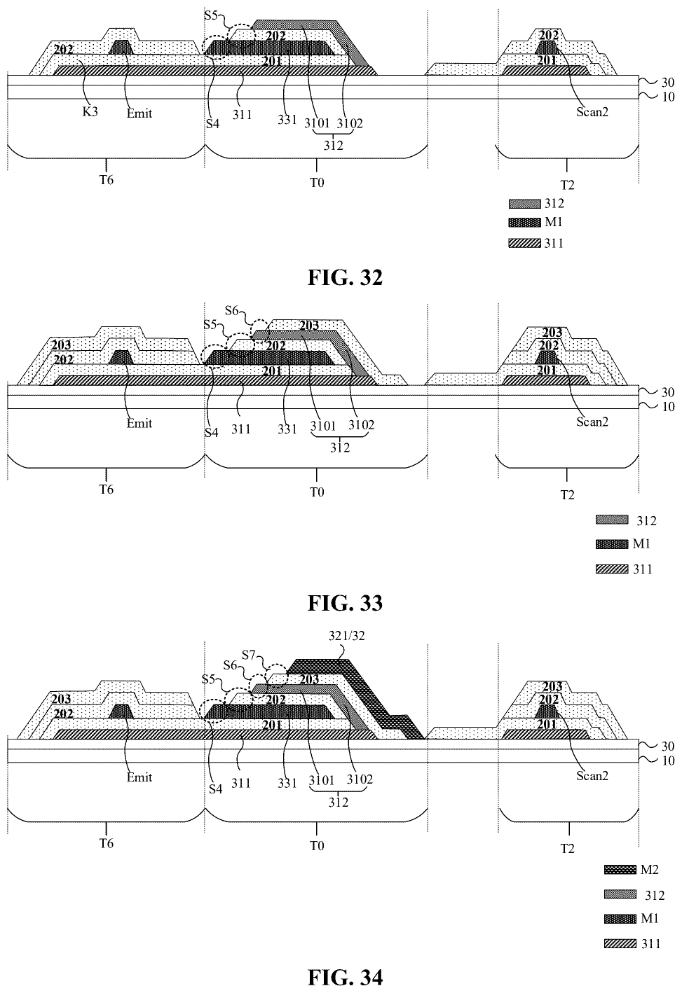

As shown in FIG. 32, in a sixth step, a layer of monocrystalline silicon is prepared on the second insulating layer 202 using a CVD process, then the monocrystalline silicon is converted to polycrystalline silicon through an ELA process, and finally the polycrystalline silicon is etched to form a second active layer 312 of the drive transistor T0. The second active layer 312 includes a first active portion 3101 and a second active portion 3102, and the second active portion 3102 contacts the third region S3 of the first active layer to achieve a connection between the first active layer 311 and the second active layer 312. Additionally, as shown in FIG. 32, in this embodiment, the first active portion 3101 exposes not only the fourth region S4 of the first gate portion 331 but also a fifth region S5 of the second insulating layer 202 to facilitate a subsequent connection between the second insulating layer 202 and a fifth insulating layer 205 through the fifth region S5.

As shown in FIG. 33, in a seventh step, a third insulating layer is prepared on one side of the layer where the second active layer 312 is located away from the substrate 10 using a CVD process, with a material such as SiOx, and then the insulating layer is etched to form a third insulating layer 203 with a specific pattern. In this embodiment, the third insulating layer 203 not only exposes the fourth region S4 of the first gate portion 331 and the fifth region S5 of the second insulating layer 202, but also exposes a sixth region S6 of the first active portion 3101 to facilitate a subsequent connection between the second active layer 312 and a third active layer 313 through the sixth region S6.

As shown in FIG. 34, in an eighth step, a second metal layer is prepared on the third insulating layer 203 using a PVD process, with a material such as at least one of Al, Cu, and Mo, and then the metal layer is etched to form a second metal layer M2 with a specific pattern. As described above, the second metal layer M2 includes an initialization signal line Vref1, a reset signal line Vref2, a first gate 32 (third gate portion 321) of the drive transistor T0, and a first capacitor plate 51 of the storage capacitor. The third gate portion 321 and the first capacitor plate 51 are electrically connected and may be integrally formed. In this embodiment, the third gate portion 321 not only exposes the fourth region S4 of the first gate portion 331, the fifth region S5 of the second insulating layer 202, and the sixth region S6 of the first active portion 3101, but also exposes a seventh region S7 of the third insulating layer 203 to facilitate a subsequent connection between the third insulating layer 203 and a fourth insulating layer 204 through the seventh region S7.

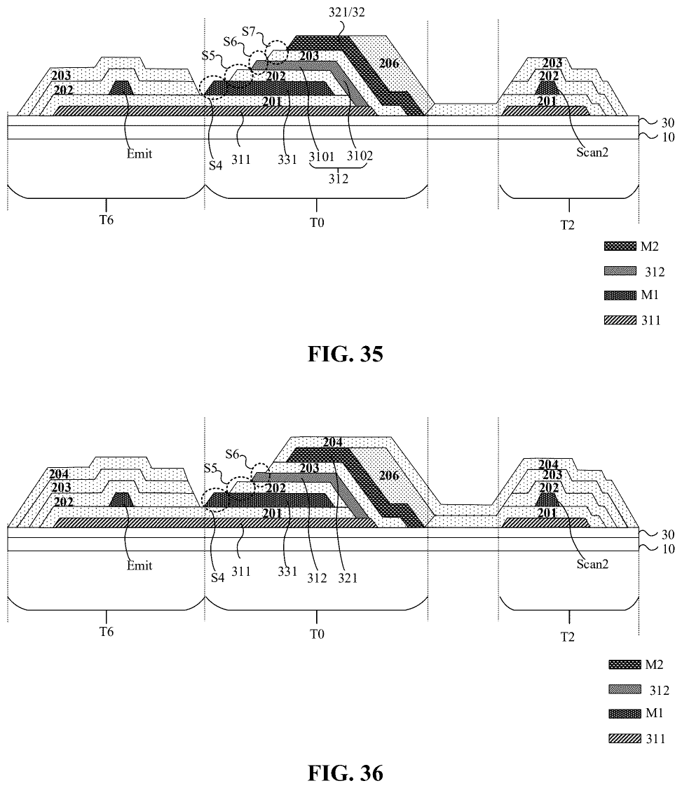

As shown in FIG. 35, in a ninth step, an interlayer insulating layer 206 is prepared on one side of the third gate portion 321 away from the second active portion 3102 using a photolithography process. Specifically, a layer of organic adhesive is coated on one side of the second metal layer M2 away from the substrate, and then a desired pattern is formed through exposure and development to obtain the interlayer insulating layer 206. Optionally, an upper surface of the interlayer insulating layer 206 is flush with an upper surface of the third gate portion 321.

As shown in FIG. 36, in a tenth step, a fourth insulating layer is prepared on one side of the second metal layer M2 and the interlayer insulating layer 206 away from the substrate 10 using a CVD process, with a material such as SiOx, and then the insulating layer is etched to form a fourth insulating layer 204 with a specific pattern. In this embodiment, the fourth insulating layer 204 is connected to the third insulating layer 203, and the fourth region S4 of the first gate portion 331, the fifth region S5 of the second insulating layer 202, and the sixth region S6 of the first active portion 3101 remain exposed.

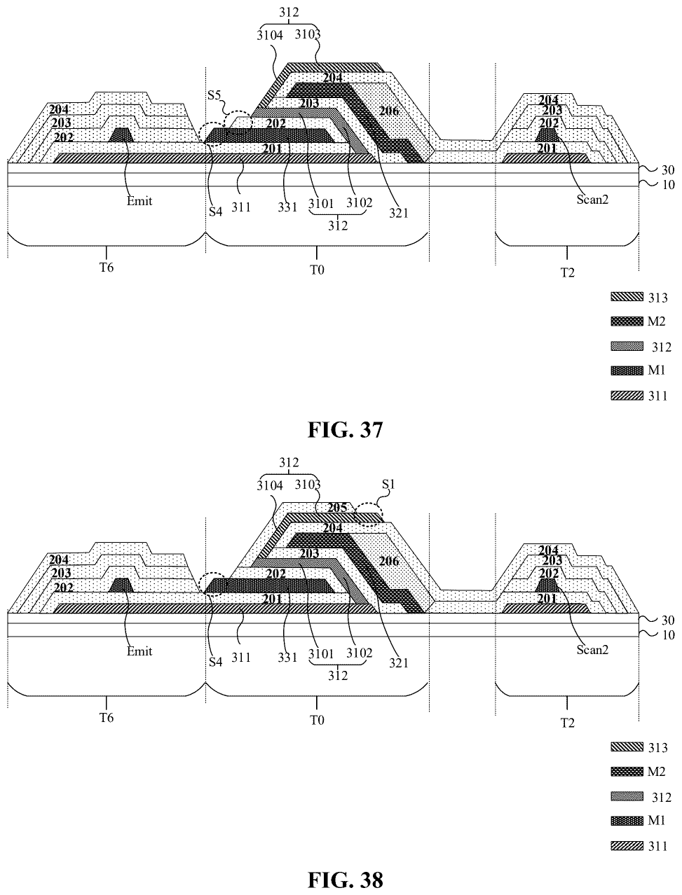

As shown in FIG. 37, in an eleventh step, a layer of monocrystalline silicon is prepared on the fourth insulating layer 204 using a CVD process, then the monocrystalline silicon is converted to polycrystalline silicon through an ELA process, and finally the polycrystalline silicon is etched to form a third active layer 313 of the drive transistor T0. The third active layer 313 includes a third active portion 3103 and a fourth active portion 3104, and the fourth active portion 3104 contacts the sixth region S6 of the first active portion 3101 to achieve a connection between the second active layer 312 and the third active layer 313. The fourth region S4 of the first gate portion 331 and the fifth region S5 of the second insulating layer 202 remain exposed.

As shown in FIG. 38, in a twelfth step, a fifth insulating layer is prepared on one side of the layer where the third active layer 313 is located away from the substrate 10 using a CVD process, with a material such as SiOx, and then the insulating layer is etched to form a fifth insulating layer 205 with a specific pattern. In this embodiment, the fifth insulating layer 205 is connected to the second insulating layer 202, and the fourth region S4 of the first gate portion 331 remains exposed. Moreover, the fifth insulating layer 205 also exposes a first region S1 of the third active portion 3103.

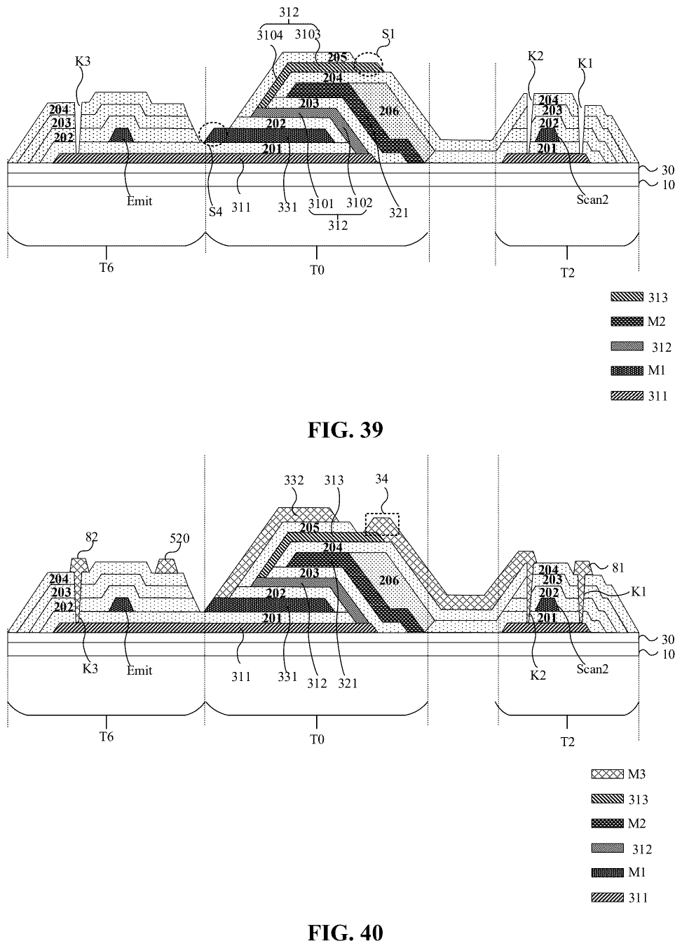

As shown in FIG. 39, in a thirteenth step, several through holes penetrating the first insulating layer 201, the second insulating layer 202, the third insulating layer 203, and the fourth insulating layer 204 are formed in the array substrate using a photolithography process. For example, as shown in FIG. 39, an eighth through hole K1, a ninth through hole K2, and a tenth through hole K3 are formed, where the eighth through hole K1 exposes a first terminal of an active layer pattern of the data write transistor T2, the ninth through hole exposes a second terminal of the active layer pattern of the data write transistor T2, and the tenth through hole K3 exposes a second terminal of an active layer pattern of the second light emission control transistor T6. Other through holes may be set as needed and are not detailed here.

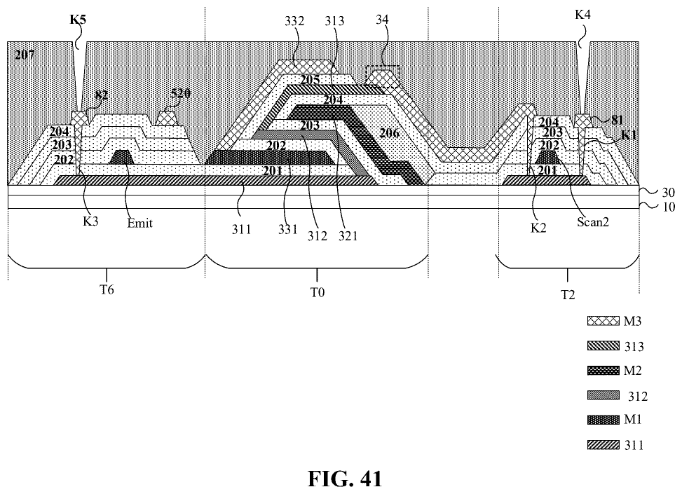

As shown in FIG. 40, in a fourteenth step, a third metal layer is prepared on one side of the fifth insulating layer 205 away from the substrate 10 using a PVD process, with a material such as at least one of Al, Cu, and Mo, and then the metal layer is etched to form a third metal layer M3 with a specific pattern. As described above, the third metal layer M3 includes a second gate portion 332 and a first electrode 34 of the drive transistor, a second capacitor plate 52 of the storage capacitor and a capacitor extension portion 520 connected to the second capacitor plate 52, a first adapter structure 81, a second adapter structure 82, a first bridge structure 91, a second bridge structure 92, and a third bridge structure 93. Except for the second capacitor plate 52 and the capacitor extension portion 520 being electrically connected (integrally formed), different structures are spaced apart from each other.

As shown in FIG. 41, in a fifteenth step, a first planarization layer is prepared on one side of the third metal layer M3 away from the substrate 10 using a coating process, with a material such as organic photoresist, and then through exposure and development, several through holes penetrating the planarization layer are formed, such as an eleventh through hole K4 and a twelfth through hole K5 shown in FIG. 41, thus forming a first planarization layer 207. The eleventh through hole K4 exposes the first adapter structure 81. The twelfth through hole K5 exposes the second adapter structure 82.

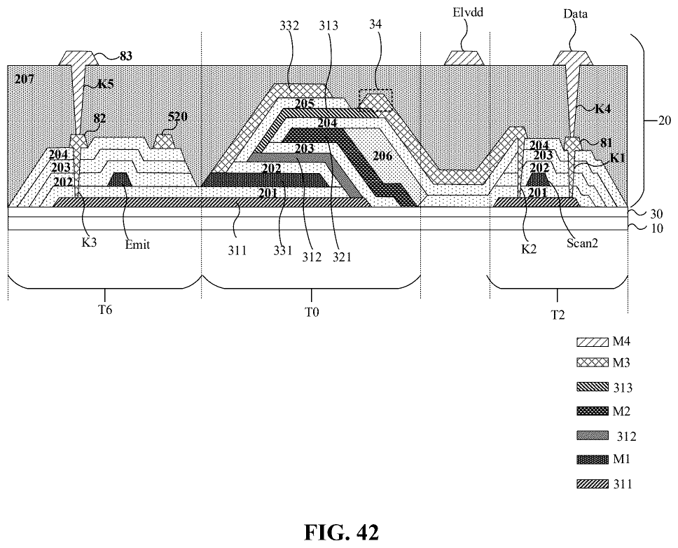

As shown in FIG. 42, in a sixteenth step, a fourth metal layer is prepared on one side of the first planarization layer 207 away from the substrate 10 using a PVD process, with a material such as at least one of Al, Cu, and Mo, and then the metal layer is etched to form a fourth metal layer M4 with a specific pattern. As described above, the fourth metal layer M4 includes patterns such as a first voltage signal line (Elvdd), a data signal line Data, and a third adapter structure 83, and different patterns are spaced apart from each other. The data signal line Data is electrically connected to the first adapter structure 81 through the eleventh through hole K4. The third adapter structure 83 is electrically connected to the second adapter structure 82 through the twelfth through hole K5.

Additionally, with reference to FIG. 21, the first voltage signal line (Elvdd) is electrically connected to the second capacitor plate 52 through a fourteenth through hole K7 and to a first terminal of an active layer pattern of the first light emission control transistor T5 through a fifteenth through hole K8.

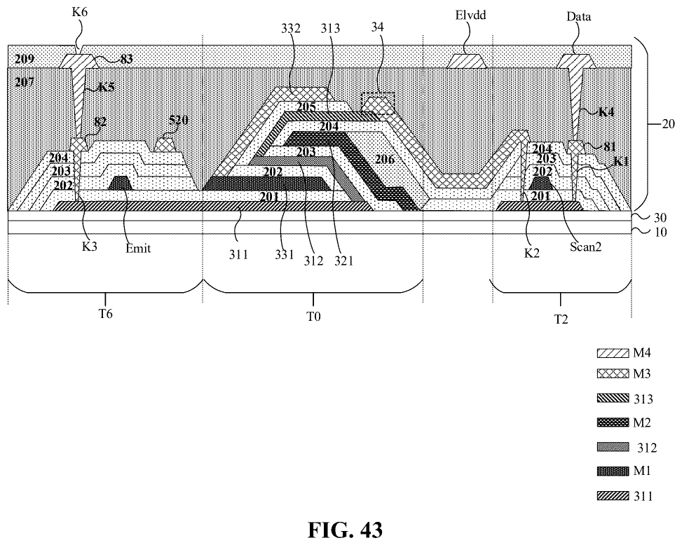

As shown in FIG. 43, in a seventeenth step, a second planarization layer is prepared on one side of the fourth metal layer M4 away from the substrate 10 using a coating process, with a material such as organic photoresist, and then through exposure and development, several through holes penetrating the planarization layer are formed, such as a thirteenth through hole K6 shown in FIG. 43, thus forming a second planarization layer 209. The thirteenth through hole K6 exposes the third adapter structure 83.

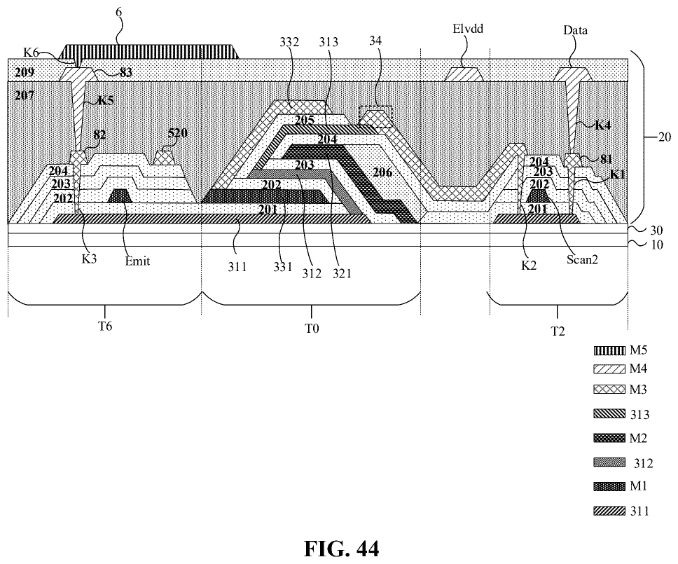

As shown in FIG. 44, in an eighteenth step, a fifth metal layer is prepared on one side of the second planarization layer 209 away from the substrate 10 using a PVD process, with a material such as a stacked structure of ITO/Ag/ITO, and then the metal layer is etched to form a fifth metal layer M5 with a specific pattern. The fifth metal layer M5 includes at least multiple anode structures 6 for subsequent electrical connections with light-emitting elements.

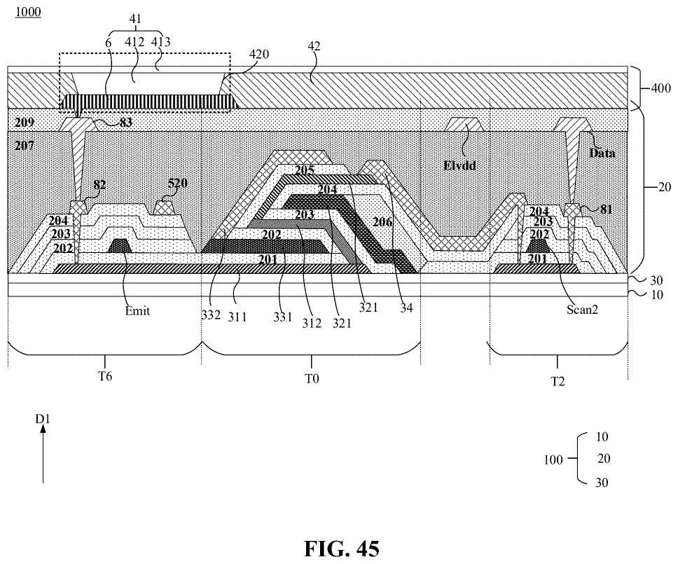

Based on the same inventive concept, embodiments of the present disclosure also provide a display panel. Exemplarily, FIG. 45 is a diagram illustrating the structure of a display panel according to an embodiment of the present disclosure. As shown in FIG. 45, the display panel 1000 includes a light-emitting layer 400 and the array substrate 100 provided by any of the preceding embodiments. The light-emitting layer 400 is located on one side of the circuit function layer 20 away from the substrate 10. The light-emitting layer 400 includes multiple light-emitting elements 41 coupled to the drive transistor T0. Since the display panel 1000 provided by the embodiments of the present disclosure includes the array substrate 100 provided by any of the preceding embodiments, the display panel 1000 has the same beneficial effects as the array substrate in the preceding embodiments, which can be referred to the descriptions of the preceding embodiments and are not repeated here.

It should be noted that the display panel provided by the embodiments of the present disclosure may be any type of LED display panel, including but not limited to OLED display panels, micro-LED display panels, and mini-LED display panels.

Exemplarily, FIG. 45 uses an OLED display panel as an example, where a light-emitting element 41 includes an anode structure 6, a light-emitting function layer 412, and a cathode 413. The light-emitting layer 400 also includes a pixel definition layer 42. The pixel definition layer 42 has a pixel opening 420 that exposes a part of the anode structure 6. The light-emitting function layer 412 is located within the pixel opening 420 and contacts the anode structure 6. The cathode 413 covers the light-emitting function layer 412. In this case, the anode structure 6 directly serves as an anode of the OLED light-emitting element.

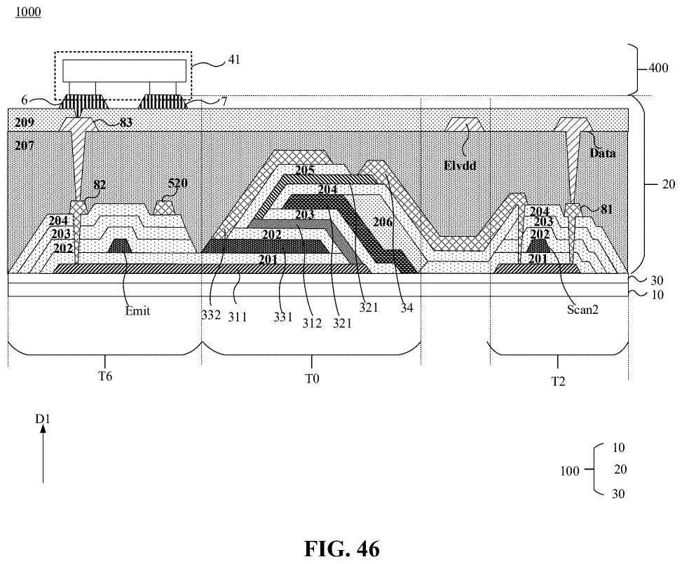

Exemplarily, FIG. 46 is another diagram illustrating the structure of a display panel according to an embodiment of the present disclosure. As shown in FIG. 46, in a micro-LED display panel, a light-emitting element 41 may be transferred to the array substrate through a mass transfer process. In this case, the anode structure 6 serves as an anode pad, and a layer where the anode structure 6 is located also includes a cathode pad 7. The anode structure 6 is used for bonding with an anode of the light-emitting element, and the cathode pad 7 is used for bonding with a cathode of the light-emitting element. It can be understood that in the array substrate, the cathode pad 7 is electrically connected to a second voltage signal line (Elvss, not shown).

Based on the same inventive concept, the present disclosure also provides a display device. The display device includes the display panel provided by any embodiment of the present disclosure. The display device may be any electronic product with a display function, including but not limited to the following categories: a mobile phone, a television, a laptop, a desktop display, a tablet computer, a digital camera, a smart bracelet, a smart glass, a vehicle-mounted display, medical equipment, industrial control equipment, and a touch interactive terminal. No special limitations are made thereto in embodiments of the present disclosure.

The preceding embodiments do not limit the scope of the present disclosure. It is to be understood by those skilled in the art that various modifications, combinations, sub-combinations, and substitutions may be performed according to design requirements and other factors. Any modifications, equivalent substitutions, improvements, and the like made within the spirit and principle of the present disclosure are within the scope of the present disclosure.

What is claimed is:

1. An array substrate, comprising:
a substrate and a circuit function layer located on one side of the substrate, wherein the circuit function layer comprises a plurality of transistors, and the plurality of transistors comprises a drive transistor;
wherein a channel region of the drive transistor comprises at least two active layers, the at least two active layers are stacked and sequentially connected along a first direction, and the first direction is a direction from the substrate toward the circuit function layer; and
the channel region comprises a first channel region and a second channel region connected along a second direction, and a length of the first channel region is less than a length of the second channel region along a third direction; and
the second direction and the third direction are intersected with each other, and the second direction and the third direction are both parallel to a plane where the substrate is located.

2. The array substrate according to claim 1, wherein the at least two active layers comprise:
a first active layer;
a second active layer located on one side of the first active layer away from the substrate, wherein the second active layer comprises a first active portion and a second active portion, and the second active portion is connected between the first active portion and the first active layer; and
a third active layer located on one side of the second active layer away from the substrate, wherein the third active layer comprises a third active portion and a fourth active portion, and the fourth active portion is connected between the first active portion and the third active portion;
wherein a plane where the second active portion is located intersects a plane where the fourth active portion is located, wherein along the first direction and the third direction, the second active portion and the fourth active portion are both located on opposite sides of the first active portion;
a part of an orthographic projection of the second active portion on the substrate is located within the first channel region, and another portion of the orthographic projection of the second active portion on the substrate is located within the second channel region; and an orthographic projection of the fourth active portion on the substrate is located within the second channel region; and
a plane where the first active layer is located, a plane where the first active portion is located, and a plane where the third active portion is located are parallel to the plane where the substrate is located, and the first active layer, the first active portion, and the third active portion overlap along the first direction.

3. The array substrate according to claim 2, further comprising:
a first insulating layer, partially located on the side of the first active layer away from the substrate;
a second insulating layer, wherein the second insulating layer is partially located between the second active layer and the first insulating layer and is connected to the first insulating layer within the channel region;
a third insulating layer, partially located on one side of the second active layer away from the second insulating layer;
a fourth insulating layer, wherein the fourth insulating layer is partially located between the third active layer and the third insulating layer and is connected to the third insulating layer within the channel region; and
a fifth insulating layer, wherein the fifth insulating layer is partially located on one side of the third active layer away from the fourth insulating layer and is connected to the second insulating layer within the channel region.

4. The array substrate according to claim 3, wherein the drive transistor further comprises at least one of a first gate or a second gate; wherein
the second gate comprises a first gate portion and a second gate portion, the first gate portion is located between the first insulating layer and the second insulating layer that are between the first active layer and the first active portion, at least a part of the second gate portion is located on one side of the fifth insulating layer away from the third active portion, and the first gate portion is electrically connected to the second gate portion; and
the first gate comprises a third gate portion, and at least a part of the third gate portion is located between the third insulating layer and the fourth insulating layer that are between the first active portion and the third active portion.

5. The array substrate according to claim 4, wherein the third gate portion extends from a region between the first active portion and the third active portion to one side of the third insulating layer away from the second active portion; and
the second gate portion extends from the side of the fifth insulating layer away from the third active portion to one side of the fifth insulating layer away from the fourth active portion and is connected to the first gate portion.

6. The array substrate according to claim 4, wherein a region where the drive transistor is located comprises a notch region, and the notch region is closest to the second channel region along the second direction and closest to the first channel region along the third direction; and
the drive transistor comprises the first gate and the second gate, along the first direction, the first gate portion, the second gate portion, and the third gate portion all overlap with the notch region; and
at least the third gate portion is electrically connected to a data signal transmission structure in the notch region, and the data signal transmission structure is spaced apart from the first active layer of the drive transistor in a same layer.

7. The array substrate according to claim 6, wherein the first gate is electrically connected to the second gate;
wherein the first gate portion is electrically connected to the third gate portion through a first through hole, the first gate portion is electrically connected to the data signal transmission structure through a second through hole, and the first through hole and the second through hole are both located in the notch region.

8. The array substrate according to claim 6, wherein the first gate and the second gate are independently controlled; and
the third gate portion is electrically connected to the data signal transmission structure through a third through hole, and the third through hole is located in the notch region and passes through a layer where the first gate portion is located; and
the first gate portion is provided with a first opening, and an orthographic projection of a region where the third through hole is located on the substrate falls within a range of an orthographic projection of a region where the first opening is located on the substrate.

9. The array substrate according to claim 6, wherein the first gate further comprises a fourth gate portion located between the first active layer and the substrate; and
the fourth gate portion is electrically connected to the data signal transmission structure through a fourth through hole, and the fourth through hole is located in the notch region.

10. The array substrate according to claim 5, wherein along the third direction, the third active portion comprises a first region at least located in the first channel region;
the first active layer comprises a second region located in the second channel region; and
an orthographic projection of the first region on the substrate and an orthographic projection of the second region on the substrate are oppositely disposed along the third direction, the first region is a first electrode lead-out region of the drive transistor, and the second region is a second electrode lead-out region of the drive transistor.

11. The array substrate according to claim 10, wherein the circuit function layer further comprises a storage capacitor, and the storage capacitor comprises a first capacitor plate and a second capacitor plate that are oppositely disposed and insulated from each other; and
along the first direction, a region where the storage capacitor is located does not overlap with the channel region; and at least a part of an orthographic projection of the storage capacitor on the substrate is located on one side of the orthographic projection of the second active portion on the substrate away from the orthographic projection of the fourth active portion on the substrate.

12. The array substrate according to claim 11, wherein the drive transistor comprises the first gate and a first electrode, and the first electrode overlaps with the first region of the third active portion;
the first capacitor plate is electrically connected to the third gate portion; and
the second capacitor plate is electrically connected to the first electrode, or the second capacitor plate is spaced apart from the first electrode in a same layer.

13. The array substrate according to claim 11, wherein a plane where the first capacitor plate is located and a plane where the second capacitor plate is located are both parallel to the plane where the substrate is located.

14. The array substrate according to claim 11, wherein the storage capacitor comprises a first capacitor portion and a second capacitor portion, a plane where the first capacitor portion is located is parallel to the plane where the substrate is located, and a plane where the second capacitor portion is located intersects the plane where the substrate is located; and
a support pillar is disposed between the first capacitor portion and the substrate.

15. The array substrate according to claim 3, further comprising an interlayer insulating layer, wherein at least a part of the interlayer insulating layer is located on one side of the third insulating layer away from the second active portion, and the fourth insulating layer covers the interlayer insulating layer; and
along the first direction, a thickness of the interlayer insulating layer is greater than a thickness of the third insulating layer.

16. The array substrate according to claim 15, wherein the drive transistor comprises a first gate, the first gate comprises a third gate portion, one part of the third gate portion is located between the third insulating layer and the fourth insulating layer that are between the first active portion and the third active portion, and another part of the third gate portion is located between the interlayer insulating layer and the third insulating layer; and
along the first direction, the interlayer insulating layer comprises a first surface and a second surface that are opposite to each other, a first portion of the third gate portion comprises a third surface and a fourth surface that are opposite to each other, the second surface is located on one side of the first surface away from the substrate, the fourth surface is located on one side of the third surface away from the substrate, and the second surface is flush with the fourth surface;
wherein a first part of the third gate portion is a part of the third gate portion located between the first active portion and the third active portion.

17. The array substrate according to claim 15, wherein the interlayer insulating layer is located between the third insulating layer and the fourth insulating layer, and the interlayer insulating layer is in contact with the third insulating layer and the fourth insulating layer; and
along the first direction, the interlayer insulating layer comprises a first insulating portion and a second insulating portion, the first insulating portion is located on the side of the third insulating layer away from the second active portion, the second insulating portion is located on one side of the fourth insulating layer away from the third active layer, and a part of the second insulating portion is located between the first active portion and the third active portion.

18. The array substrate according to claim 10, wherein the drive transistor further comprises a first electrode, and the first electrode overlaps with the first region of the third active portion; and
the circuit function layer further comprises a data write transistor, an active layer pattern of the data write transistor is spaced apart from the first active layer in a same layer, a gate of the data write transistor is spaced apart from the first gate portion in a same layer, a first end of the active layer pattern of the data write transistor is electrically connected to a data signal line through a through hole, and a second end of the active layer pattern of the data write transistor is electrically connected to the first electrode through a through hole.

19. A display panel, comprising an array substrate and a light-emitting layer;
wherein the array substrate comprises: a substrate and a circuit function layer located on one side of the substrate, wherein the circuit function layer comprises a plurality of transistors, and the plurality of transistors comprises a drive transistor;
wherein a channel region of the drive transistor comprises at least two active layers, the at least two active layers are stacked and sequentially connected along a first direction, and the first direction is a direction from the substrate toward the circuit function layer; and
the channel region comprises a first channel region and a second channel region connected along a second direction, and along a third direction, a length of the first channel region is less than a length of the second channel region; and
the second direction and the third direction are intersected with each other, and the second direction and the third direction are both parallel to a plane where the substrate is located;
wherein the light-emitting layer is located on one side of the circuit function layer away from the substrate and comprises a plurality of light-emitting elements coupled to the drive transistor.
